(19) United States
(12) Patent Application Publication
(10) Pub. No.: US 2024/0411055 A1
(43) Pub. Date: Dec. 12, 2024

(54) ANTI-GLARE FILM, AND POLARIZING PLATE, SURFACE PLATE, IMAGE DISPLAY PANEL, AND IMAGE DISPLAY DEVICE THAT USE SAME

(71) Applicant: DAI NIPPON PRINTING CO., LTD., Tokyo (JP)

(72) Inventors: Mitsuhiro KUZUHARA, Okayama-shi, Okayama (JP); Yukimitsu IWATA, Okayama-shi, Okayama (JP); Jun TSUJIMOTO, Bizen-shi, Okayama (JP); Shigeki MURAKAMI, Okayama-shi, Okayama (JP); Gen FURUI, Okayama-shi, Okayama (JP)

(21) Appl. No.: 18/701,546

(22) PCT Filed: Oct. 27, 2022
(86) PCT No.: PCT/JP2022/040049

§ 371 Date: Apr. 15, 2024

(30) Foreign Application Priority Data
Oct. 28, 2021 (JP) 2021-176743

(51) Int. Cl. G02B 1/111; G02B 5/30

(52) U.S. Cl. CPC G02B 1/111; G02B 5/3025

(57) ABSTRACT

Provided is an anti-glare film excellent in anti-glare properties and scratch resistance and capable of suppressing reflected scattered light. An anti-glare film including an anti-glare layer, the anti-glare film having an uneven surface, wherein for an amplitude spectrum of elevation of the uneven surface, when a sum of amplitudes corresponding to spatial frequencies of 0.005 μm⁻¹, 0.010 μm⁻¹, and 0.015 μm⁻¹ is defined as AM1 and an amplitude at a spatial frequency of 0.300 μm⁻¹ is defined as AM2, AM1 is more than 0.4000 μm and 1.0000 μm or less, and AM2 is 0.0050 μm or more and 0.0500 μm or less.

### TECHNICAL FIELD

The present disclosure relates to an anti-glare film, and a polarizing plate, a surface plate, an image display panel, and an image display device that use the same.

### BACKGROUND ART

An anti-glare film for suppressing reflection of a background such as illumination or a person may be installed on the surface of an image display device such as a monitor of a TV, a laptop PC, or a desktop PC.

The anti-glare film has a basic structure in which an anti-glare layer having an unevenly shaped surface is provided on a transparent substrate. As such an anti-glare film, for example, Patent Literature 1 to 4 and the like have been proposed.

### CITATION LIST

### Patent Literature

PTL 1: JP 2005-234554 A
PTL 2: JP 2009-86410 A
PTL 3: JP 2009-265500 A
PTL 4: WO 2013/015039 A

### SUMMARY OF INVENTION

### Technical Problem

Conventional anti-glare films such as those described in PTL 1 to 4 impart anti-glare properties to such an extent that a reflected image is blurred, and therefore it has been difficult to sufficiently suppress reflection of a background such as illumination or a person.

On the other hand, by increasing the degree of roughness of the surface unevenness of the anti-glare layer, reflection is sufficiently suppressed, and therefore, the anti-glare properties can be enhanced. However, simply increasing the degree of roughness of the surface unevenness increases the intensity of reflected scattered light, resulting in a problem of impairing the contrast of the image display device.

Further, the conventional anti-glare films as in PTL 1 to 4 has insufficient scratch resistance in some cases.

An object of the present disclosure is to provide an anti-glare film excellent in anti-glare properties and scratch resistance, and capable of suppressing reflected scattered light.

### Solution to Problem

The present disclosure provides an anti-glare film according to the following [1] to [2], and a polarizing plate, a surface plate, an image display panel, and a display device that use the same:
[1] An anti-glare film comprising an anti-glare layer, the anti-glare film having an uneven surface, wherein for amplitude spectrum of elevation of the uneven surface, when a sum of amplitudes corresponding to spatial frequencies of 0.005 μm⁻¹, 0.010 μm⁻¹, and 0.015 μm⁻¹ is defined as AM1 and an amplitude at a spatial frequency of 0.300 μm⁻¹ is defined as AM2, AM1 is more than 0.4000 μm and 1.0000 μm or less, and AM2 is 0.0050 μm or more and 0.0500 μm or less.
[2] The anti-glare film according to [1], wherein AM1/AM2 is 1.0 or more and 90.0 or less.
[3] The anti-glare film according to [1] or [2], wherein when a root mean square inclination of the uneven surface is defined as Δq and a root mean square wavelength of the uneven surface is defined as λq, Δq is 0.250 μm/μm or more and λq is 17.000 μm or less.
[4] The anti-glare film according to any one of [1] to [3], wherein when a root mean roughness of the uneven surface is defined as Rq, Rq is 0.300 μm or more.
[5] The anti-glare film according to any one of [1] to [4], having a haze of JIS K7135:2000 of 40% or more and 98% or less.
[6] The anti-glare film according to any one of [1] to [5], wherein the anti-glare layer comprises a binder resin and particles.
[7] The anti-glare film according to [6], wherein when a thickness of the anti-glare layer is defined as T and an average particle size of the particles is defined as D, D/T is 0.20 or more and 0.96 or less.
[8] The anti-glare film according to [6] or [7], wherein the particles are contained in an amount of 10 parts by mass or more and 200 parts by mass or less based on 100 parts by mass of the binder resin.
[9] The anti-glare film according to any one of [6] to [8], wherein the particles are inorganic particles.
[10] The anti-glare film according to [9], wherein the anti-glare layer further comprises organic particles.
[11] The anti-glare film according to any one of [6] to [10], wherein the binder resin comprises a cured product of an ionizing radiation-curable resin composition and a thermoplastic resin.
[12] The anti-glare film according to any one of [1] to [11], further comprising an anti-reflection layer on the anti-glare layer, a surface of the anti-reflection layer being the uneven surface.
[13] A polarizing plate comprising:
   a polarizer;
   a first transparent protective plate disposed on one side of the polarizer; and
   a second transparent protective plate disposed on the other side of the polarizer, wherein
   at least one of the first transparent protective plate and the second transparent protective plate is the anti-glare film according to any one of [1] to [12], and
   a surface opposite to the uneven surface of the anti-glare film and the polarizer are disposed so as to face each other.
[14] A surface plate for an image display device, the surface plate comprising:
   a resin plate or a glass plate; and
   a protective film bonded to the resin plate or the glass plate, wherein
   the protective film is the anti-glare film according to any one of [1] to [12], and a surface opposite to the uneven surface of the anti-glare film and the resin plate or the glass plate are disposed so as to face each other.
[15] An image display panel comprising:
   a display element; and
   an optical film disposed on a light-emitting surface side of the display element, wherein
   the image display panel comprises the anti-glare film according to any one of [1] to
[12] as the optical film, and
   the anti-glare film is disposed so that a surface of the anti-glare film on the uneven surface side is disposed so as to face the opposite side to the display element.
[16] An image display device comprising the image display panel according to [15], wherein the anti-glare film is disposed on an outermost surface.

### Advantageous Effects of Invention

The anti-glare film of the present disclosure and the polarizing plate, the surface plate, the image display panel, and the image display device that use the same are excellent in anti-glare properties and scratch resistance, and capable of suppressing reflected scattered light.

### BRIEF DESCRIPTION OF DRAWINGS

FIG. 1 is a schematic cross-sectional view showing one embodiment of an anti-glare film of the present disclosure.

FIG. 2 is a schematic view for explaining the behavior of light incident on an anti-glare layer.

FIG. 3 is a cross-sectional view showing one embodiment of an image display panel of the present disclosure.

FIG. 4 is a view for explaining a method of calculating an amplitude spectrum of an elevation of an uneven surface.

FIG. 5 is a view for explaining a method of calculating an amplitude spectrum of an elevation of an uneven surface.

FIG. 6 is a graph showing the relationship between spatial frequency and amplitude of an anti-glare film of Example 1.

FIG. 7 is a graph showing the relationship between spatial frequency and amplitude of an anti-glare film of Example 2.

FIG. 8 is a graph showing the relationship between spatial frequency and amplitude of an anti-glare film of Example 3.

FIG. 9 is a graph showing the relationship between spatial frequency and amplitude of an anti-glare film of Example 4.

FIG. 10 is a graph showing the relationship between spatial frequency and amplitude of an anti-glare film of Example 5.

FIG. 11 is a graph showing the relationship between spatial frequency and amplitude of an anti-glare film of Example 6.

FIG. 12 is a graph showing the relationship between spatial frequency and amplitude of an anti-glare film of Example 7.

FIG. 13 is a graph showing the relationship between spatial frequency and amplitude of an anti-glare film of Comparative Example 1.

FIG. 14 is a graph showing the relationship between spatial frequency and amplitude of an anti-glare film of Comparative Example 2.

FIG. 15 is a graph showing the relationship between spatial frequency and amplitude of an anti-glare film of Comparative Example 3.

FIG. 16 is a graph showing the relationship between spatial frequency and amplitude of an anti-glare film of Comparative Example 4.

### DESCRIPTION OF EMBODIMENTS

Embodiments of the present disclosure will be described below.

### [Anti-Glare Film]

An anti-glare film of the present disclosure is an anti-glare film including an anti-glare layer, the anti-glare film having an uneven surface, wherein for amplitude spectrum of elevation of the uneven surface, when a sum of amplitudes corresponding to spatial frequencies of 0.005 μm⁻¹, 0.010 μm⁻¹, and 0.015 μm⁻¹ is defined as AM1 and an amplitude at a spatial frequency of 0.300 μm⁻¹ is defined as AM2, AM1 is more than 0.4000 μm and 1.0000 μm or less, and AM2 is 0.0050 μm or more and 0.0500 μm or less.

In the present specification, AM1 is the sum of the amplitudes of the three spatial frequencies and is represented by the following formula.

$$AM 1 = amplitude at spatial frequency 0.005 {µm}^{- 1} + amplitude at spatial frequency 0.01 {µm}^{- 1} + amplitude at spatial frequency 0.015 {µm}^{- 1}$$

Since the spatial frequency is a discrete value depending on the length of one side, a spatial frequency corresponding to 0.005 μm⁻¹, 0.010 μm⁻¹, 0.015 μm⁻¹, and 0.300 μm⁻¹ may not be obtained. In the present specification, in a case where there is no spatial frequency that matches the value, the amplitude of a spatial frequency having a value closest to the value is extracted.

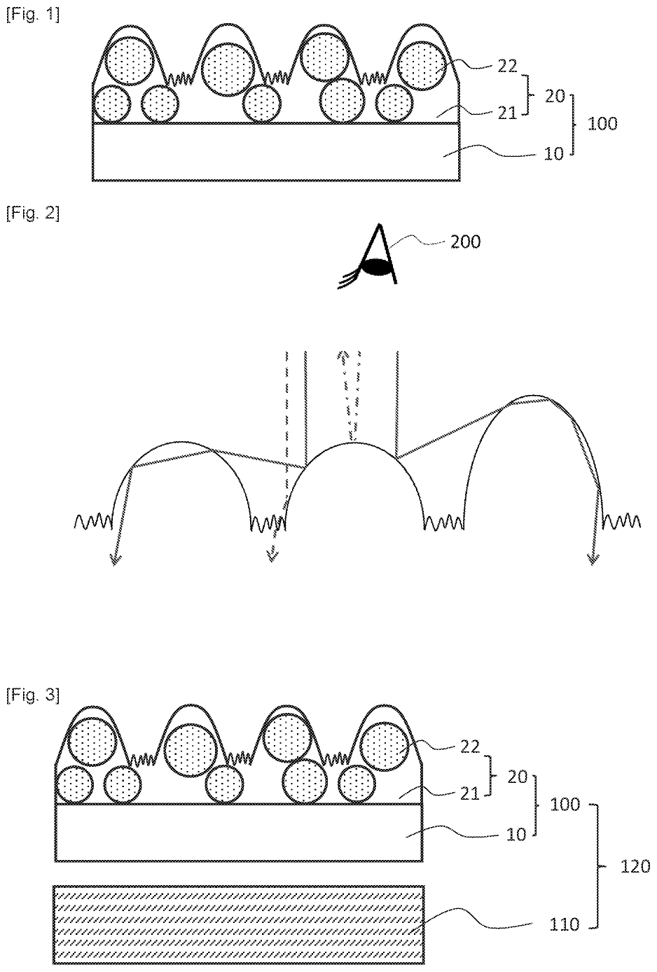

FIG. 1 is a schematic cross-sectional view of the cross-sectional shape of an anti-glare film 100 of the present disclosure.

The anti-glare film 100 of FIG. 1 has an anti-glare layer 20 and has an uneven surface. In FIG. 1, a surface of the anti-glare layer 20 is the uneven surface of the anti-glare film. The anti-glare film 100 of FIG. 1 has the anti-glare layer 20 on a transparent substrate 10. The anti-glare layer 20 in FIG. 1 has a binder resin 21 and particles 22.

FIG. 1 is a schematic cross-sectional view. That is, the scale of each layer constituting the anti-glare film 100, the scale of each material, and the scale of the surface unevenness are schematic for easy illustration, and are different from the actual scale. The same applies to FIGS. 2 to 4.

The anti-glare film of the present disclosure is not limited to the laminated structure shown in FIG. 1 as long as it has an anti-glare layer with an uneven surface where AM1 is more than 0.4000 μm and 1.0000 μm or less, and AM2 is 0.0050 μm or more and 0.0500 μm or less. For example, the anti-glare film may have a single-layer structure of an anti-glare layer, or may have a layer other than the transparent substrate and the anti-glare layer. Examples of the layers other than the transparent substrate and the anti-glare layer include an anti-reflection layer and an anti-fouling layer. When another layer is provided on the anti-glare layer, a surface of the other layer may be the uneven surface of the anti-glare film.

A preferred embodiment of the anti-glare film includes an anti-glare layer on a transparent substrate, wherein a surface of the anti-glare layer opposite to the transparent substrate is the uneven surface.

### <Transparent Substrate>

The anti-glare film preferably has a transparent substrate in order to improve ease of production of the anti-glare film and ease of handling of the anti-glare film.

The transparent substrate preferably has light transmittance, smoothness, heat resistance, and excellent mechanical strength. Examples of such a transparent substrate include plastic films such as polyester, triacetyl cellulose (TAC), cellulose diacetate, cellulose acetate butyrate, polyamide, polyimide, polyether sulfone, polysulfone, polypropylene, polymethylpentene, polyvinyl chloride, polyvinyl acetal, polyether ketone, polymethyl methacrylate, polycarbonate, polyurethane, and amorphous olefin (Cyclo-Olefin-Polymer: COP). The transparent substrate may be a laminate of two or more plastic films.

Among the plastic films, in order to improve the mechanical strength and the dimensional stability, a polyester film subjected to a stretching process is preferable, and a polyester film subjected to a biaxial stretching process is more preferable. Examples of the polyester film include a polyethylene terephthalate film and a polyethylene naphthalate film. A TAC film and an acrylic film are preferable because light transmittance and optical isotropy can be easily improved. A COP film and the polyester film are preferable in terms of excellent weather resistance.

The thickness of the transparent substrate is preferably 5 μm or more and 300 μm or less, more preferably 20 μm or more and 200 μm or less, and still more preferably 30 μm or more and 120 μm or less.

When it is desired to reduce the thickness of the anti-glare film, the upper limit of the thickness of the transparent substrate is preferably 60 μm or less, and more preferably 50 μm or less. When the transparent substrate is a low moisture-permeable substrate such as polyester, COP, or acrylic, the upper limit of the thickness of the transparent substrate for forming a thin film is preferably 40 μm or less, and more preferably 20 μm or less. Even in the case of a large screen, when the upper limit of the thickness of the transparent substrate is within the aforementioned range, strain is less likely to occur, which is also preferable.

The thickness of the transparent substrate can be measured with Digimatic standard outside micrometer (product number “MDC-25SX” available from MITUTOYO CORPORATION) or the like. As the thickness of the transparent substrate, the average of the values measured at any ten points thereof may be the value described above.

Examples of the preferred range of the thickness of the transparent substrate include 5 μm or more and 300 μm or less, 5 μm or more and 200 μm or less, 5 μm or more and 120 μm or less, 5 μm or more and 60 μm or less, 5 μm or more and 50 μm or less, 5 μm or more and 40 μm or less, 5 μm or more and 20 μm or less, 20 μm or more and 300 μm or less, 20 μm or more and 200 μm or less, 20 μm or more and 120 μm or less, 20 μm or more and 60 μm or less, 20 μm or more and 50 μm or less, 20 μm or more and 40 μm or less, 30 μm or more and 300 μm or less, 30 μm or more and 200 μm or less, 30 μm or more and 120 μm or less, 30 μm or more and 60 μm or less, 30 μm or more and 50 μm or less, and 30 μm or more and 40 μm or less.

A surface of the transparent substrate may be subjected to a physical treatment such as a corona discharge treatment or a chemical treatment, or an easily adhesive layer may be formed on the surface of the transparent substrate to improve adhesiveness.

### <Uneven Surface>

The anti-glare film is required to have an uneven surface.

The anti-glare film requires that for amplitude spectrum of elevation of the uneven surface, AM1 is more than 0.4000 μm and 1.0000 μm or less, and AM2 is 0.0050 μm or more and 0.0500 μm or less.

When there is no other layer on the anti-glare layer, the surface of the anti-glare layer may satisfy the above conditions of the uneven surface. When there is another layer on the anti-glare layer, the surface of the other layer may satisfy the above conditions of the uneven surface.

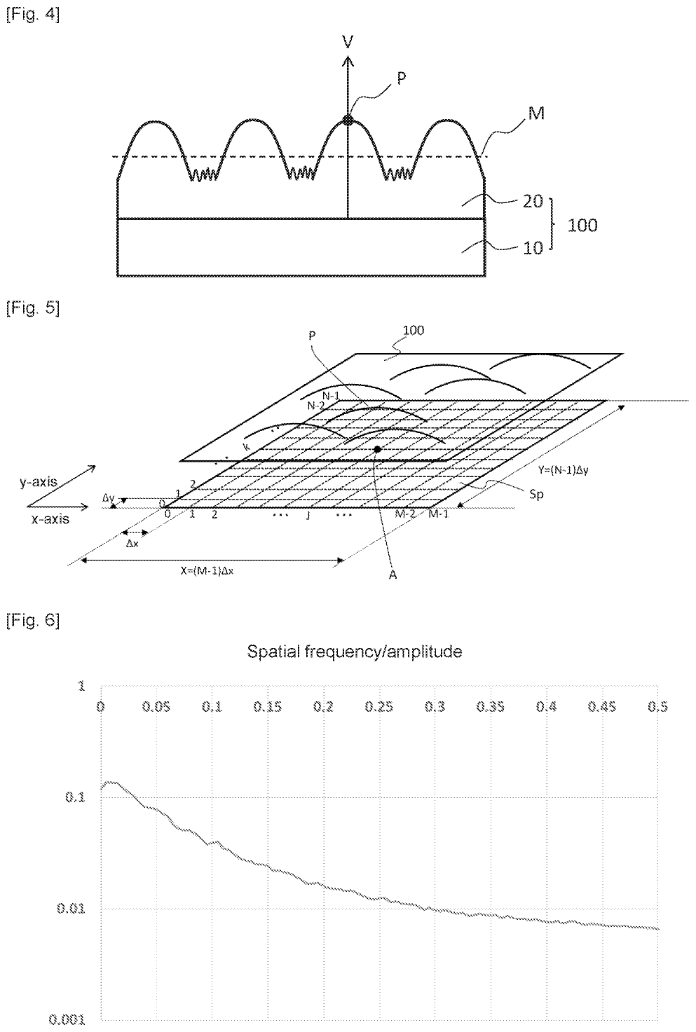

In the present specification, “elevation of the uneven surface” means the linear distance in the direction of the normal V of the anti-glare film between any point P on the uneven surface and a virtual plane M having an average height of the uneven surface (see FIG. 4). The elevation of the virtual plane M is set to 0 μm as a reference. The direction of the normal V is the normal direction of the virtual plane M. When the elevation of any point P is higher than the average height, the elevation is positive, and when the elevation of any point P is lower than the average height, the elevation is negative.

In the present specification, words including “elevation” mean elevations based on the above average height, unless otherwise specified.

The spatial frequency and amplitude can be obtained by Fourier transforming the three-dimensional coordinate data of the uneven surface. The method of calculating the spatial frequency and amplitude from the three-dimensional coordinate data of the uneven surface herein will be described later.

### <<AM1, AM2>>

For amplitude spectrum of elevation of the uneven surface, it can be said that the spatial frequency is generally correlated with “the reciprocal of the interval between the convex portions”, and the amplitude is generally correlated with “the amount of change in the elevation of the convex portions having a predetermined interval”. The spatial frequency of 0.005 μm⁻¹ indicates that the interval is about 200 μm, the spatial frequency of 0.010 μm⁻¹ indicates that the interval is about 100 μm, the spatial frequency of 0.015 μm⁻¹ indicates that the interval is about 67 μm, and the spatial frequency of 0.300 μm⁻¹ indicates that the interval is about 3 μm. It can be said that “the amount of change in the elevation of the convex portions having a predetermined interval” is generally proportional to the absolute value of each individual height of convex portions having a predetermined interval.

Therefore, it can be said that it is indirectly defined that the uneven surfaces in which AM1 is more than 0.4000 μm and 1.0000 μm or less and AM2 is 0.0050 μm or more and 0.0500 μm or less include the following convex portion groups i and ii. Since the value AM2 is sufficiently smaller than the value AM1, it can be said that the absolute value of the height of the convex portions ii is smaller than the absolute value of the height of the convex portions i.

<Convex Portion Group of i>

Those in which a plurality of convex portions i are disposed at intervals of about 67 μm or more and 200 μm or less, and the absolute value of the height of the convex portions i is within a predetermined range.

<Convex Portion Group of ii>

Those in which a plurality of convex portions ii are disposed at intervals of about 3 μm, and the absolute value of the height of the convex portions ii is within a predetermined range.

It is considered that the uneven surface having the convex portion groups of i and ii described above can exhibit excellent anti-glare properties and can suppress reflected scattered light mainly for the following reasons (x1) to (x5). Explanation will be given below with reference to FIG. 2. In FIG. 2, the convex portions with large intervals in the uneven structure indicates convex portions i. In FIG. 2, convex portions with small intervals between a convex portion i and another convex portion i, and convex portions with small intervals in the uneven structure present at both left and right ends of FIG. 2 are convex portions ii. In FIG. 2, the outer edges of the convex portions having large absolute values of height are schematically drawn with a smooth line, but the outer edges may have fine unevenness. For example, it is considered that the anti-glare films of Examples have fine unevenness on the outer edges of the convex portions having large absolute values of height.
(x1) In the convex portion group of i, the interval between adjacent convex portions i is not too long, and the convex portions i have a predetermined height. Therefore, most of the reflected light reflected by the surface of any convex portion i is incident on the adjacent convex portion i. Then, the light repeats total reflection inside the adjacent convex portion i, and finally travels opposite to the observer 200 (solid line image in FIG. 2).
(x2) Reflected light of the light incident on the steep slope of any convex portion i travels opposite to the observer 200 regardless of the adjacent convex portion i (dashed line image in FIG. 2).
(x3) Normally, the region between a convex portion i and another convex portion i is likely to form a substantially flat portion that causes specularly reflected light. However, in the anti-glare film of the present disclosure, since the convex portion group ii is easily formed in the region between a convex portion i and another convex portion i, the proportion of the specularly reflected light in the reflected light reflected in the region can be reduced.
(x4) The reflected light reflected in the region between a convex portion i and another convex portion i tends to collide with the adjacent peaks. Since the value AM2 is sufficiently smaller than the value AM1 in the anti-glare film of the present disclosure, the reflected light reflected in the region between a convex portion i and another convex portion i more tends to collide with the adjacent peaks. Therefore, the angular distribution of the reflected light reflected by the region is not biased to a predetermined angle, and becomes a substantially uniform angular distribution.
(x5) The reflected light of the light incident on the gentle slope of the convex portion i travels toward the observer 200 (dashed-dotted line image in FIG. 2). Since the angular distribution of the gentle slope of the convex portion i is uniform, the angular distribution of the reflected light is also uniform without being biased to a specific angle.

First, from (x1) to (x3) above, it is considered that the anti-glare properties can be improved at a predetermined level because the reflected scattered light can be suppressed.

Furthermore, from (x4) and (x5) above, even when a small amount of reflected scattered light is generated, the angular distribution of the reflected scattered light can be made uniform. Even when the amount of the reflected scattered light is very small, when the angular distribution of the reflected scattered light is biased to a specific angle, the light is recognized as reflected light. Therefore, the anti-glare properties can be made extremely good from (x4) and (x5) above.

Furthermore, from (x1) to (x5) above, the observer can hardly perceive the reflected scattered light, which gives the anti-glare film a jet-black appearance, and furthermore, gives the image display device a luxurious feel.

When AM1 is more than 0.4000 μm and 1.0000 μm or less, and AM2 is 0.0050 μm or more and 0.0500 μm or less, the effects of (x1) to (x5) above are more likely to occur, which makes it possible to have good anti-glare properties and also makes it easier to give jet-black appearance by suppressing reflected scattered light.

When AM1 is less than 0.4000 μm, since a scratched material tends to be contacted with the uneven surface of the anti-glare film, the scratch resistance cannot be made good. When AM2 is more than 0.0500 μm, scratches on the uneven surface of the anti-glare film if made is conspicuous, and thus the scratch resistance cannot be made good.

AM1 is preferably 0.4050 μm or more and 0.8000 μm or less, more preferably 0.4800 μm or more and 0.7600 μm or less, and further preferably 0.5200 μm or more and 0.7200 μm or less in order to facilitate the effects of (x1) to (x5) and to improve the scratch resistance.

When AM1 is too small, the anti-glare properties tend to be particularly insufficient. Further, when AM1 is too small, since a scratched material tends to be contacted with the uneven surface of the anti-glare film, the scratch resistance tends to decrease.

On the other hand, when AM1 is too large, the resolution of the video tends to decrease. Further, when AM1 is too large, the proportion of light totally reflected by the uneven surface increases, so the transmittance of light such as image light entering from the opposite side of the uneven surface tends to decrease. Also, when AM1 is too large, the proportion of light reflected to the observer side increases due to the increase in the number of convex portions having a large absolute value of height, and thus the reflected scattered light may become conspicuous. Therefore, it is suitable that AM1 is not too large in order to suppress the deterioration of the resolution and the transmittance and to further suppress the reflected scattered light.

AM2 is preferably 0.0060 μm or more and 0.0450 μm or less, more preferably 0.0070 μm or more and 0.0400 μm or less, further preferably 0.0080 μm or more and 0.0300 μm or less, and still further preferably 0.0090 μm or more and 0.0200 μm or less in order to facilitate the effects of (x1) to (x5) and to improve the scratch resistance.

When AM2 is too large, the resolution of the video tends to decrease. Therefore, it is also suitable that AM2 is not too large in order to suppress the deterioration of the resolution.

When a plurality of options of a numerical upper limit value and a plurality of options of a numerical lower limit value are described in a constituent described in the present specification, one selected from the options of the upper limit and one selected from the options of the lower limit can be combined to form an embodiment of a numerical range.

For example, embodiments of AM1 include more than 0.4000 μm and 1.0000 μm or less, more than 0.4000 μm and 0.8000 μm or less, more than 0.4000 μm and 0.7600 μm or less, more than 0.4000 μm and 0.7200 μm or less, 0.4050 μm or more and 1.0000 μm or less, 0.4050 μm or more and 0.8000 μm or less, 0.4050 μm or more and 0.7600 μm or less, 0.4050 μm or more and 0.7200 μm or less, 0.4800 μm or more and 1.0000 μm or less, 0.4800 μm or more and 0.8000 μm or less, 0.4800 μm or more and 0.7600 μm or less, 0.4800 μm or more and 0.7200 μm or less, 0.5200 μm or more and 1.0000 μm or less, 0.5200 μm or more and 0.8000 μm or less, 0.5200 μm or more and 0.7600 μm or less, and 0.5200 μm or more and 0.7200 μm or less.

Embodiments of AM2 include 0.0050 μm or more and 0.0500 μm or less, 0.0050 μm or more and 0.0450 μm or less, 0.0050 μm or more and 0.0400 μm or less, 0.0050 μm or more and 0.0300 μm or less, 0.0050 μm or more and 0.0200 μm or less, 0.0060 μm or more and 0.0500 μm or less, 0.0060 μm or more and 0.0450 μm or less, 0.0060 μm or more and 0.0400 μm or less, 0.0060 μm or more and 0.0300 μm or less, 0.0060 μm or more and 0.0200 μm or less, 0.0070 μm or more and 0.0500 μm or less, 0.0070 μm or more and 0.0450 μm or less, 0.0070 μm or more and 0.0400 μm or less, 0.0070 μm or more and 0.0300 μm or less, 0.0070 μm or more and 0.0200 μm or less, 0.0080 μm or more and 0.0500 μm or less, 0.0080 μm or more and 0.0450 μm or less, 0.0080 μm or more and 0.0400 μm or less, 0.0080 μm or more and 0.0300 μm or less, 0.0800 μm or more and 0.0200 μm or less, 0.0090 μm or more and 0.0500 μm or less, 0.0090 μm or more and 0.0450 μm or less, 0.0090 μm or more and 0.0400 μm or less, 0.0090 μm or more and 0.0300 μm or less, and 0.0090 μm or more and 0.0200 μm or less.

In the present specification, the numerical values for amplitude spectrum of elevations such as AM1 and AM2, numerical values for optical properties such as haze and total light transmittance, and numerical values for surface shapes such as Δq and λq mean the average values of the measurement values at sixteen points.

In the present specification, regarding the 16 measurement sites, it is preferable that 1 cm region from the outer edge of a measurement sample is left as a margin, in a region on the inner side of the margin, lines that divide the region into five equal parts in the vertical direction and the horizontal direction are drawn, and measurement is performed mainly at 16 sites of the intersection points. For example, in the case of a rectangle measurement sample, 0.5 cm region from the outer edge of the rectangle is left as a margin, and measurement is performed mainly at 16 sites of the intersection points of dotted lines that divide a region on the inner side of the margin in the vertical direction and the horizontal direction. In addition, the average value of the measurement values at 16 sites is regarded as the value of each parameter. When the measurement sample has a shape other than a rectangle such as a circle, an ellipse, a triangle, or a pentagon, it is preferable to draw a rectangle inscribed inside these shapes and measurement is performed at each of the sixteen points of the rectangle according to the above method.

In the present specification, various parameters such as values about the amplitude spectrum of elevation such as AM1 and AM2, values about optical properties such as haze and total light transmittance, values about surface shapes such as Δq and λq are measured at a temperature of 23±5° C. and a relative humidity of 40% or more and 65% or less, unless otherwise specified. Further, before starting each measurement, the measurement is performed after exposing the target sample to the atmosphere for 30 minutes or more and 60 minutes or less.

In the present specification, AM1 is the sum of the amplitudes of the three spatial frequencies. That is, in the present specification, three intervals are taken into consideration for the intervals of the convex portions in AM1. In this manner, in the present specification, a plurality of intervals are taken into consideration for AM1, and thus, by setting AM1 to a predetermined value, an increase in reflection light due to the uniform intervals between the convex portions can easily be suppressed.

In the present disclosure, when the average of the amplitudes corresponding to the spatial frequencies of 0.005 μm⁻¹, 0.010 μm⁻¹, and 0.015 μm⁻¹ is defined as AM1ave, AM1ave is preferably 0.1300 μm or more and 0.3300 μm or less, more preferably 0.1350 μm or more and 0.2700 μm or less, further preferably 0.1600 μm or more and 0.2500 μm or less, and still further preferably 0.1700 μm or more and 0.2400 μm or less.

Embodiments within a preferable range of AM1ave include 0.1300 μm or more and 0.3300 μm or less, 0.1300 μm or more and 0.2700 μm or less, 0.1300 μm or more and 0.2500 μm or less, 0.1300 μm or more and 0.2400 μm or less, 0.1350 μm or more and 0.3300 μm or less, 0.1350 μm or more and 0.2700 μm or less, 0.1350 μm or more and 0.2500 μm or less, 0.1350 μm or more and 0.2400 μm or less, 0.1600 μm or more and 0.3300 μm or less, 0.1600 μm or more and 0.2700 μm or less, 0.1600 μm or more and 0.2500 μm or less, 0.1600 μm or more and 0.2400 μm or less, 0.1700 μm or more and 0.3300 μm or less, 0.1700 μm or more and 0.2700 μm or less, 0.1700 μm or more and 0.2500 μm or less, and 0.1700 μm or more and 0.2400 μm or less.

AM1ave can be represented by the following formula.

$$AM 1 ave = ( amplitude at spatial frequency 0.005 {µm}^{- 1} + amplitude at \\ spatial frequency 0.01 {µm}^{- 1} + amplitude at \\ spatial frequency 0.015 {µm}^{- 1 )} / 3$$

In the present disclosure, when the amplitude corresponding to the spatial frequency of 0.005 μm⁻¹ is defined as AM1-1, the amplitude corresponding to the spatial frequency of 0.010 μm⁻¹ is defined as AM1-2, and the amplitude corresponding to the spatial frequency of 0.015 μm⁻¹ is defined as AM1-3, AM1-1, AM1-2, and AM1-3 are preferably in the following ranges. By setting AM1-1, AM1-2, and AM1-3 within the following ranges, it becomes easier to suppress the uniformity of the intervals between the convex portions, an increase in reflected light can easily be suppressed.

AM1-1 is preferably 0.1300 μm or more and 0.3900 μm or less, more preferably 0.1500 μm or more and 0.3300 μm or less, still more preferably 0.1600 μm or more and 0.3000 μm or less, and further preferably 0.1700 μm or more and 0.2700 μm or less. Examples of the preferred range of AM1-1 include 0.1300 μm or more and 0.3900 μm or less, 0.1300 μm or more and 0.3300 μm or less, 0.1300 μm or more and 0.3000 μm or less, 0.1300 μm or more and 0.2700 μm or less, 0.1500 μm or more and 0.3900 μm or less, 0.1500 μm or more and 0.3300 μm or less, 0.1500 μm or more and 0.3000 μm or less, 0.1500 μm or more and 0.2700 μm or less, 0.1600 μm or more and 0.3900 μm or less, 0.1600 μm or more and 0.3300 μm or less, 0.1600 μm or more and 0.3000 μm or less, 0.1600 μm or more and 0.2700 μm or less, 0.1700 μm or more and 0.3900 μm or less, 0.1700 μm or more and 0.3300 μm or less, 0.1700 μm or more and 0.3000 μm or less, and 0.1700 μm or more and 0.2700 μm or less.

AM1-2 is preferably 0.1300 μm or more and 0.3300 μm or less, more preferably 0.1500 μm or more and 0.2700 μm or less, still more preferably 0.1600 μm or more and 0.2500 μm or less, and further preferably 0.1700 μm or more and 0.2400 μm or less.

Examples of the preferred range of AM1-2 include 0.1300 μm or more and 0.3300 μm or less, 0.1300 μm or more and 0.2700 μm or less, 0.1300 μm or more and 0.2500 μm or less, 0.1300 μm or more and 0.2400 μm or less, 0.1500 μm or more and 0.3300 μm or less, 0.1500 μm or more and 0.2700 μm or less, 0.1500 μm or more and 0.2500 μm or less, 0.1500 μm or more and 0.2400 μm or less, 0.1600 μm or more and 0.3300 μm or less, 0.1600 μm or more and 0.2700 μm or less, 0.1600 μm or more and 0.2500 μm or less, 0.1600 μm or more and 0.2400 μm or less, 0.1700 μm or more and 0.3300 μm or less, 0.1700 μm or more and 0.2700 μm or less, 0.1700 μm or more and 0.2500 μm or less, and 0.1700 μm or more and 0.2400 μm or less.

AM1-3 is preferably 0.1300 μm or more and 0.3300 μm or less, more preferably 0.1500 μm or more and 0.2700 μm or less, still more preferably 0.1600 μm or more and 0.2500 μm or less, and further preferably 0.1700 μm or more and 0.2400 μm or less.

Examples of the preferred range of AM1-3 include 0.1300 μm or more and 0.3300 μm or less, 0.1300 μm or more and 0.2700 μm or less, 0.1300 μm or more and 0.2500 μm or less, 0.1300 μm or more and 0.2400 μm or less, 0.1500 μm or more and 0.3300 μm or less, 0.1500 μm or more and 0.2700 μm or less, 0.1500 μm or more and 0.2500 μm or less, 0.1500 μm or more and 0.2400 μm or less, 0.1600 μm or more and 0.3300 μm or less, 0.1600 μm or more and 0.2700 μm or less, 0.1600 μm or more and 0.2500 μm or less, 0.1600 μm or more and 0.2400 μm or less, 0.1700 μm or more and 0.3300 μm or less, 0.1700 μm or more and 0.2700 μm or less, 0.1700 μm or more and 0.2500 μm or less, and 0.1700 μm or more and 0.2400 μm or less.

In the anti-glare film of the present disclosure, AM1/AM2 is preferably 1.0 or more and 90.0 or less, more preferably 3.0 or more and 80.0 or less, still more preferably 10.0 or more and 70.0 or less, and further preferably 15.0 or more and 60.0 or less, 50.0 or more and 60.0 or less in order to improve the balance of the convex portions having different cycles and to facilitate the effects of (x1) to (x5) to occur.

Examples of the preferred range of AM1/AM2 include 1.0 or more and 90.0 or less, 1.0 or more and 80.0 or less, 1.0 or more and 70.0 or less, 1.0 or more and 60.0 or less, 3.0 or more and 90.0 or less, 3.0 or more and 80.0 or less, 3.0 or more and 70.0 or less, 3.0 or more and 60.0 or less, 10.0 or more and 90.0 or less, 10.0 or more and 80.0 or less, 10.0 or more and 70.0 or less, 10.0 or more and 60.0 or less, 15.0 or more and 90.0 or less, 15.0 or more and 80.0 or less, 15.0 or more and 70.0 or less, 15.0 or more and 60.0 or less, 50.0 or more and 90.0 or less, 50.0 or more and 80.0 or less, 50.0 or more and 70.0 or less, and 50.0 or more and 60.0 or less.

### —Calculation Method for AM1 and AM2—

In the present specification, for amplitude spectrum of elevation of the uneven surface, AM1 means the sum of amplitudes corresponding to spatial frequencies of 0.005 μm⁻¹, 0.010 μm⁻¹, and 0.015 μm⁻¹. In the present specification, for the amplitude spectrum, AM2 means the amplitude at the spatial frequency of 0.300 μm⁻¹. A method of calculating AM1 and AM2 in the present specification will be described below.

First, as described above, in the present specification, “elevation of the uneven surface” means the linear distance in the direction of the normal V of the anti-glare film between any point P on the uneven surface and a virtual plane M having an average height of the uneven surface (see FIG. 4). The elevation of the virtual plane M is set to 0 μm as a reference. The direction of the normal V is the normal direction of the virtual plane M.

When the orthogonal coordinates in the uneven surface of the anti-glare film are represented by (x, y), the elevation of the uneven surface of the anti-glare film can be represented by a two-dimensional function h(x, y) of the coordinates (x, y).

The elevation of the uneven surface is preferably measured using an interference microscope. Examples of interference microscopes include “New View” series available from Zygo Corporation.

The horizontal resolution required for the measuring instrument is at least 5 μm or less, preferably 1 μm or less, and the vertical resolution is at least 0.01 μm or less, preferably 0.001 μm or less.

Considering that the spatial frequency resolution is 0.0050 μm¹, the elevation measurement area is preferably an area of at least 200 μm×200 μm.

Next, a method for obtaining the amplitude spectrum of elevation from the two-dimensional function h(x, y) will be described. First, from the two-dimensional function h(x, y), the amplitude spectrum Hx(fx) in the x direction and the amplitude spectrum Hy(fy) in the y direction are obtained by Fourier transform defined by the following formulas (1a) and (1b).

$${H}_{x} ( {f}_{x} ) ≡ {\int }_{- ∞}^{∞} h ( x ) exp ( - 2 π {if}_{x} x ) dx \qquad ( 1 a )$$

$${H}_{y} ( {f}_{y} ) ≡ {\int }_{- ∞}^{∞} h ( y ) exp ( - 2 π {if}_{y} y ) dy \qquad ( 1 b )$$

wherein fx and fy are the frequencies in the x and y directions, respectively, and have the dimensions of the inverse of the length. π in the formulas (1a) and (1b) is the pi and i is the imaginary unit. The amplitude spectrum H(f) can be obtained by averaging the amplitude spectrum Hx(fx) in the x direction and the amplitude spectrum Hy(fy) in the y direction. This amplitude spectrum H(f) represents the spatial frequency distribution of the uneven surface of the anti-glare film.

Hereinafter, the method for obtaining the amplitude spectrum H(f) of the elevation of the uneven surface of the anti-glare film will be described more specifically. The three-dimensional information of the surface shape actually measured by the above interference microscope is generally obtained as discrete values. That is, the three-dimensional information of the surface shape actually measured by the interference microscope is obtained as elevations corresponding to many measurement points.

FIG. 5 is a schematic view showing how the function h(x, y) representing elevation is discretely obtained. As shown in FIG. 5, when the orthogonal coordinates in the plane of the anti-glare layer are represented by (x, y) and the lines divided by Δx in the x-axis direction and the lines divided by Δy in the y-axis direction on the projection plane Sp are represented by broken lines, the elevation of the uneven surface is obtained as a discrete elevation value at each intersection of the broken lines on the projection plane Sp in actual measurement.

The number of elevation values obtained depends on the measurement range and Δx and Δy. As shown in FIG. 5, when the measurement range in the x-axis direction is X=(M−1)Δx and the measurement range in the y-axis direction is Y=(N−1)Δy, the number of obtained elevation values is M×N.

As shown in FIG. 5, when the coordinates of the point of interest A on the projection plane Sp are (jΔx, kΔy), the elevation of the point P on the uneven surface corresponding to the point of interest A can be represented by hoΔx, kΔy). Here, j is 0 or more and M−1 or less, and k is 0 or more and N−1 or less.

Here, the measurement intervals Δx and Δy depend on the horizontal resolution of the measuring instrument, and in order to accurately evaluate the fine uneven surface, both Δx and Δy are preferably 5 μm or less as described above, and more preferably 2 μm or less. Both the measurement ranges X and Y are preferably 200 μm or more, as described above.

Thus, in actual measurement, the function representing the elevation of the uneven surface is obtained as a discrete function h(x,y) having M×N values. N discrete functions Hx(fx) and M discrete functions Hy(fy) are obtained by subjecting the discrete function h(x, y) obtained by the measurement to the discrete Fourier transformation defined by the following formulas (2a) and (2b) in the x direction and the y direction, respectively, and the amplitude spectrum H(f) is obtained by obtaining absolute values (=amplitudes) of the functions and then averaging all the functions according to the following formula (2c). In the present specification, M=N and Δx=Δy. In the following formulas (2a) to (2c), “1” is an integer of −M/2 or more and M/2 or less, and “m” is an integer of −N/2 or more and N/2 or less. Δfx and Δfy are frequency intervals in the x direction and the y direction, respectively, and are defined by the formulas (3) and (4) below.

$${H}_{xk} ( {f}_{x} ) = {H}_{xk} ( l Δ {f}_{x} ) ≡ \frac{1}{M} {\sum }_{j = 0}^{M - 1} h ( j Δ x , k Δ y ) exp ( - 2 π ij Δ xl Δ {f}_{x} ) \qquad ( 2 a )$$

$${H}_{yj} ( {f}_{y} ) = {H}_{yj} ( m Δ {f}_{y} ) ≡ \frac{1}{N} {\sum }_{k = 0}^{N - 1} h ( j Δ x , k Δ y ) exp ( - 2 π ik Δ ym Δ {f}_{y} ) \qquad ( 2 b )$$

$$H ( f ) = H ( l Δ {f}_{x} ( = k Δ {f}_{y} ) ) ≡ [ \frac{1}{N} {\sum }_{k = 0}^{N - 1} \vert {H}_{xk} ( {f}_{x} ) \vert + \frac{1}{M} {\sum }_{j = 0}^{M - 1} \vert {H}_{yj} ( {f}_{y} ) \vert ] / 2 \qquad ( 2 c )$$

$$Δ {f}_{x} ≡ \frac{1}{M Δ x} \qquad ( 3 )$$

$$Δ {f}_{y} ≡ \frac{1}{N Δ y} \qquad ( 4 )$$

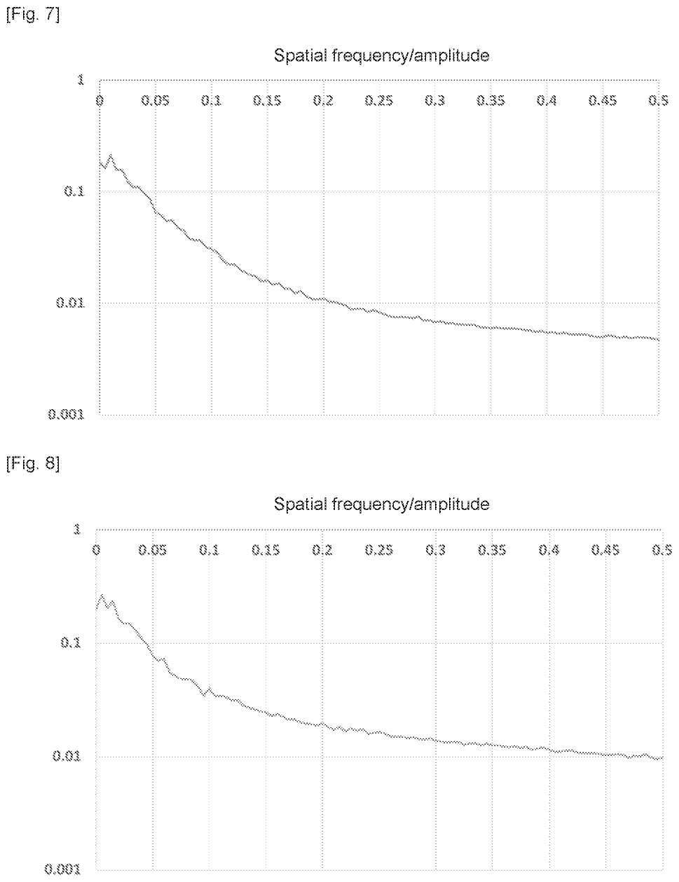

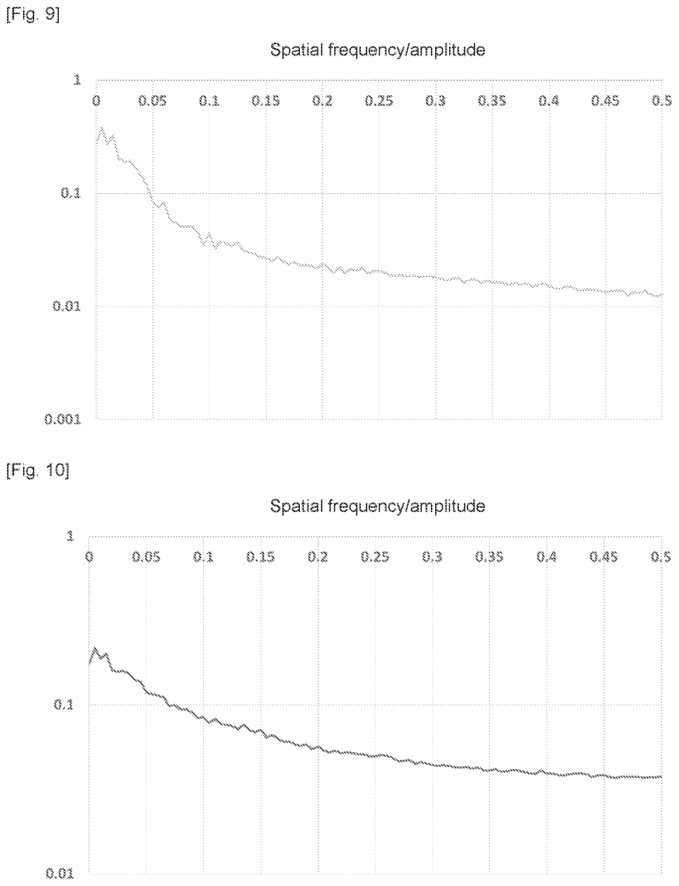

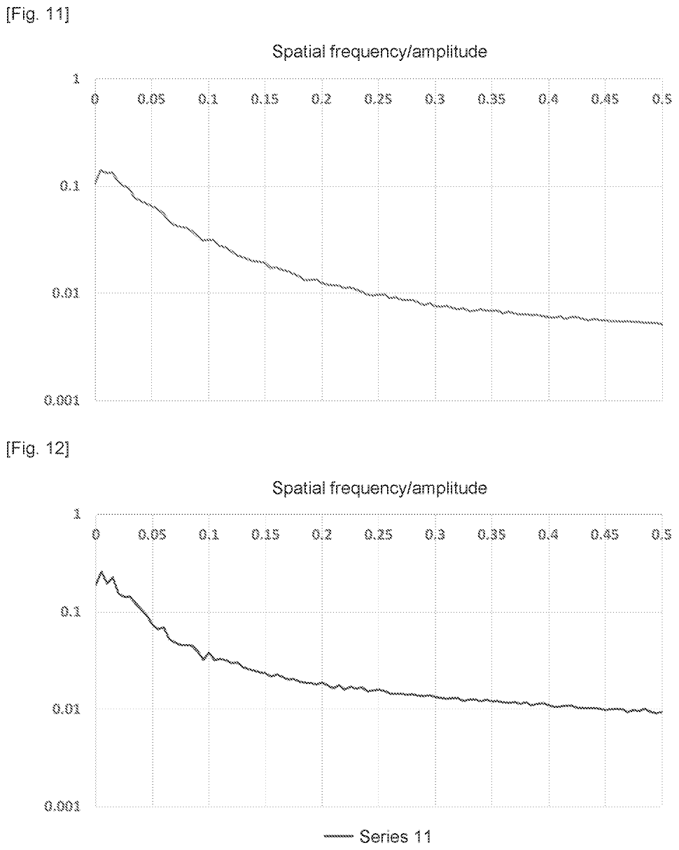

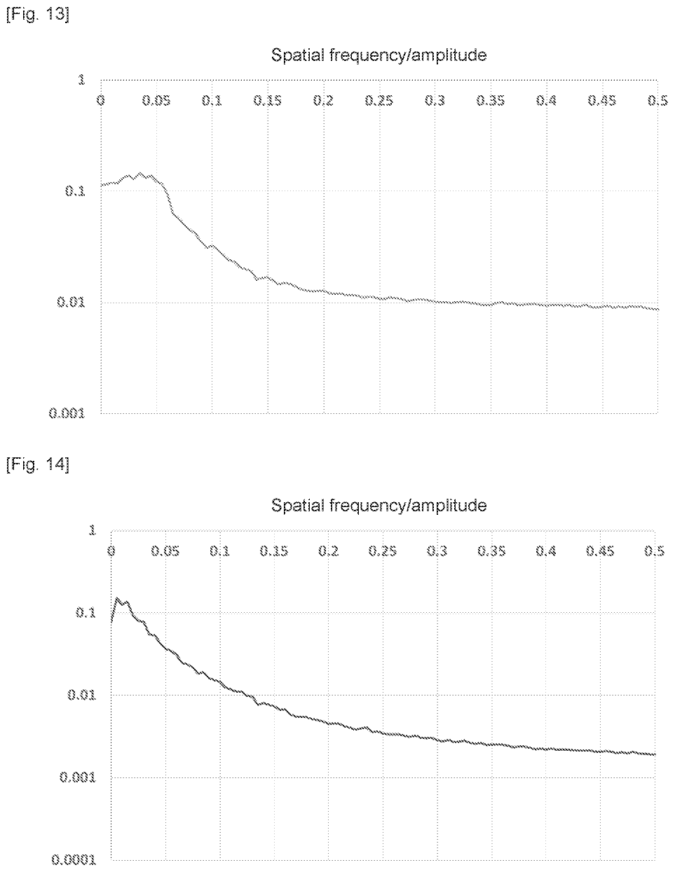

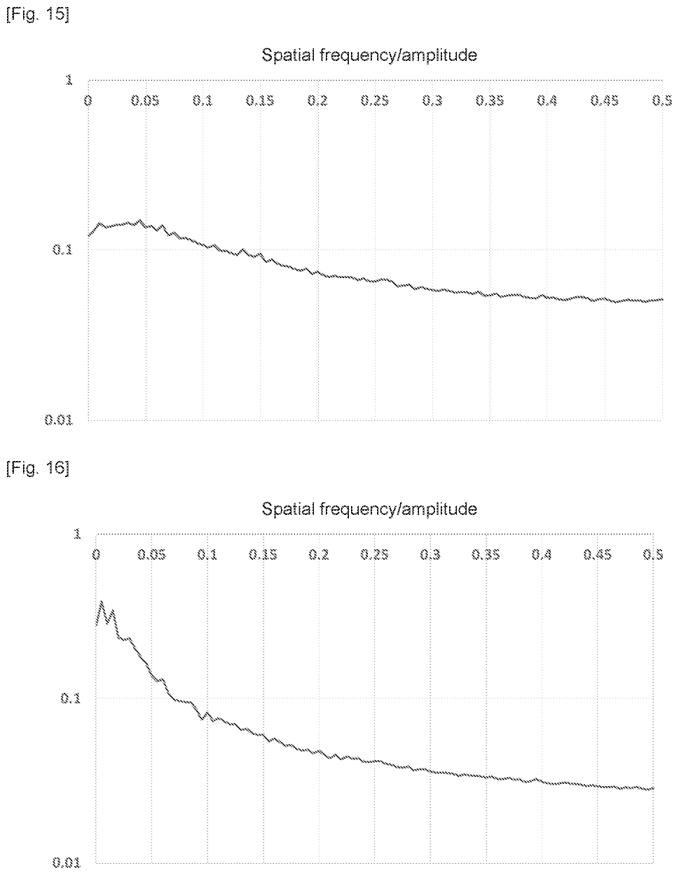

The discrete function H(f) of the amplitude spectrum calculated as described above represents the spatial frequency distribution of the uneven surface of the anti-glare film. FIGS. 6 to 16 show the discrete function H(f) of the amplitude spectrum of the elevation of the uneven surface of Examples 1 to 7 and Comparative Examples 1 to 4. In the figures, the horizontal axis represents the spatial frequency (unit: “μm⁻¹”), and the vertical axis represents the amplitude (unit: “μm”).

<<Δq and λq>>

In the anti-glare film of the present disclosure, when a root mean square inclination of the uneven surface is defined as Δq and a root mean square wavelength of the uneven surface is defined as λq, Δq is preferably 0.250 μm/μm or more, and λq is preferably 17.000 μm or less.

Δq is correlated with an inclination angle of the uneven surface. More specifically, a larger Δq means a larger inclination angle of the uneven surface. Since Δq is a square parameter, Δq tends to reflect an effect by a larger inclination angle than an average inclination angle. Therefore, Δq is a parameter different from the average inclination angle, which is a parameter simply averaging all inclinations.

λq is correlated with intervals of the unevenness of the uneven surface. More specifically, a smaller λq means a narrower interval of the unevenness of the uneven surface. As represented by the formula (A) described later, λq is a parameter calculated from the square parameters Δq and Rq. Thus, λq is a parameter strongly reflecting intervals of the unevenness with a large height difference and a large inclination angle among the unevenness. Therefore, λq is a parameter different from RSm of JIS, which is a parameter averaging all intervals of the unevenness.

Therefore, the uneven surface having Δq of 0.250 μm/μm or more and λq of 17.000 μm or less means that the unevenness with a large inclination angle is present with narrow intervals. As above, the presence of the unevenness with a large inclination angle with narrow intervals easily regulates AM1 and AM2 within the aforementioned range. Particularly, reducing λq can easily impart a jet-black appearance to the anti-glare film.

Δq is more preferably 0.300 μm/μm or more, further preferably 0.325 μm/μm or more, and still further preferably 0.350 μm/μm or more.

When Δq is too large, video light tends to be scattered when transmitting the anti-glare film, and dark-room contrast tends to decrease. When Δq is too large, a reflectance of video light increases, and a transmittance of the video light tends to decrease. Thus, Δq is preferably 0.800 μm/μm or less, more preferably 0.700 μm/μm or less, and further preferably 0.600 μm/μm or less.

Examples of the preferred range of Δq include 0.250 μm/μm or more and 0.800 μm/μm or less, 0.250 μm/μm or more and 0.700 μm/μm or less, 0.250 μm/μm or more and 0.600 μm/μm or less, 0.300 μm/μm or more and 0.800 μm/μm or less, 0.300 μm/μm or more and 0.700 μm/μm or less, 0.300 μm/μm or more and 0.600 μm/μm or less, 0.325 μm/μm or more and 0.800 μm/60 μm or less, 0.325 μm/μm or more and 0.700 μm/μm or less, 0.325 μm/μm or more and 0.600 μm/μm or less, 0.350 μm/μm or more and 0.800 μm/μm or less, 0.350 μm/μm or more and 0.700 μm/μm or less, and 0.350 μm/μm or more and 0.600 μm/μm or less.

λq is more preferably 16.000 μm or less, more preferably 15.000 μm or less, more preferably 14.500 μm or less, more preferably 13.500 μm or less, and more preferably 12.000 μm or less.

When λq is too small, the video light tends to be scattered when transmitting the anti-glare film, and the dark-room contrast tends to decrease. Thus, λq is preferably 3.000 μm or more, more preferably 5.000 μm or more, and further preferably 7.000 μm or more. Examples of the preferred range of λq include 3.000 μm or more and 17.000 μm or less, 3.000 μm or more and 16.000 μm or less, 3.000 μm or more and 15.000 μm or less, 3.000 μm or more and 14.500 μm or less, 3.000 μm or more and 13.500 μm or less, 3.000 μm or more and 12.000 μm or less, 5.000 μm or more and 17.000 μm or less, 5.000 μm or more and 16.000 μm or less, 5.000 μm or more and 15.000 μm or less, 5.000 μm or more and 14.500 μm or less, 5.000 μm or more and 13.500 μm or less, 5.000 μm or more and 12.000 μm or less, 7.000 μm or more and 17.000 μm or less, 7.000 μm or more and 16.000 μm or less, 7.000 μm or more and 15.000 μm or less, 7.000 μm or more and 14.500 μm or less, 7.000 μm or more and 13.500 μm or less, and 7.000 μm or more and 12.000 μm or less.

### <<Rq>>

To improve the anti-glare properties, Rq of the anti-glare film of the present disclosure is preferably 0.300 μm or more, more preferably 0.350 μm or more, and further preferably 0.400 μm or more.

When Rq is too large, AM1 and/or AM2 may become too large. Thus, Rq is preferably 1.100 μm or less, more preferably 1.000 μm or less, and further preferably 0.900 μm or less.

Embodiments within a preferable range of Rq include 0.300 μm or more and 1.100 μm or less, 0.300 μm or more and 1.000 μm or less, 0.300 μm or more and 0.900 μm or less, 0.350 μm or more and 1.100 μm or less, 0.350 μm or more and 1.000 μm or less, 0.350 μm or more and 0.900 μm or less, 0.400 μm or more and 1.100 μm or less, 0.400 μm or more and 1.000 μm or less, and 0.400 μm or more and 0.900 μm or less.

In the present specification, Δq means a parameter in which “a root mean square inclination on a roughness curve RΔq” defined in JIS B0601:2001 is extended to three-dimension.

In the present specification, Rq means a parameter in which “a root mean square height on a roughness curve Rq” defined in JIS B0601:2001 is extended to three-dimension.

In the present specification, λq means a parameter represented by the following formula (A) from Δq and Rq.

$$λ q = {2}^{1.5} π ( Rq / Δ q ) \qquad ( A )$$

Δq, Rq, and λq are preferably measured by using an interference microscope. Examples of interference microscopes include trade name “New View” series available from Zygo Corporation. By using the measurement/analysis application software “MetroPro” attached to the “New View” series described above, Δq, Rq, and λq can be easily calculated.

Measurement conditions for measuring Δq, Rq, and λq by using “New View” series described above is preferably according to conditions described in Examples. For example, “Filter Low Wavelen” (corresponding to λc in JIS B0601) is preferably 800 μm. “Camera Res” (resolution) is preferably 0.3 μm or more and 0.5 μm or less.

### <Anti-Glare Layer>

The anti-glare layer is the layer responsible for the suppression of reflected scattered light and the center of antiglare properties.

### <<Method for Forming Anti-Glare Layer>>

The anti-glare layer can be formed, for example, by (A) a method using an embossing roll, (B) an etching treatment, (C) molding with a mold, (D) formation of a coating film by coating, or the like. Among these methods, (C) molding with a mold is suitable for easily obtaining a stable surface shape, and (D) formation of a coating film by coating is suitable for productivity and compatibility with various products.

When the anti-glare layer is formed by (D), examples of the method include a method (d1) in which a coating liquid containing a binder resin and particles is applied to form unevenness by the particles, and a method (d2) in which a coating liquid containing any resin and a resin having poor compatibility with the resin is applied to phase-separate the resin to form unevenness. (d1) is more preferable than (d2) in that the balance between AM1 and AM2 is easily improved. Also, (d1) is more preferable than (d2) in that Δq, λq and Rq can be easily suppressed.

### <<Thickness>>

The thickness T of the anti-glare layer is preferably 2 μm or more and 10 μm or less, more preferably 4 μm or more and 8 μm or less, in order to achieve a good balance among curl suppression, mechanical strength, hardness, and toughness.

The thickness of the anti-glare layer can be calculated, for example, by selecting 20 arbitrary points in a cross-sectional photograph of the anti-glare film taken with a scanning transmission electron microscope (STEM) and averaging the values. It is preferable that the acceleration voltage of the STEM is 10 kV or more and 30 kV or less, and the magnification of the STEM is 1000 times or more and 7000 times or less.

Embodiments of a preferable range of the thickness of the anti-glare layer include 2 μm or more and 10 μm or less, 2 μm or more and 8 μm or less, 4 μm or more and 10 μm or less, and 4 μm or more and 8 μm or less.

### <<Components>>

The anti-glare layer mainly contains a resin component, and optionally contains particles such as organic particles and inorganic fine particles, and additives such as a refractive index adjuster, an anti-static agent, an anti-fouling agent, an ultraviolet absorber, a light stabilizer, an antioxidant, a viscosity modifier, and a thermal polymerization initiator.

The anti-glare layer preferably contains a binder resin and particles. Examples of the particles include organic particles and inorganic particles, and inorganic particles are preferred. That is, the anti-glare layer more preferably contains a binder resin and inorganic particles. The anti-glare layer further preferably contains a binder resin, inorganic particles, and organic particles.

### —Particles—

Examples of the particles include organic particles and inorganic particles.

Examples of the organic particles include particles made of polymethyl methacrylate, a polyacryl-styrene copolymer, a melamine resin, polycarbonate, polystyrene, polyvinyl chloride, a benzoguanamine-melamine-formaldehyde condensate, silicone, a fluorine-based resin, and a polyester-based resin.

Examples of the inorganic particles include silica, alumina, zirconia, and titania, and silica is preferred. Among the inorganic particles, irregularly shaped inorganic particles are preferred, and irregularly shaped silica is more preferred.

By using the irregularly shaped inorganic particles such as irregularly shaped silica as the particles, a steep roughness interval is easily formed, and thus Δq can be easily set to be large.

When the irregularly shaped inorganic particles such as irregularly shaped silica are used as the particles, a content ratio of the irregularly shaped inorganic particles in the anti-glare layer is preferably increased in order to easily set Δq and λq within the aforementioned range. By increasing the content ratio of the irregularly shaped inorganic particles in the anti-glare layer, it is possible to form a shape in which the irregularly shaped inorganic particles are spread all over the surface to easily set λq to be small. Further, by adding organic particles in addition to the irregularly shaped inorganic particles, excessive aggregation of the irregularly shaped inorganic particles is suppressed and the narrow roughness structure can be retained, and thus λq can be set to be small. By regulating Δq and λq within the aforementioned ranges, AM1 and AM2 are easily set to be within the above ranges. A mass ratio between the inorganic irregularly shaped particles and the organic particles is preferably 5:1 to 1:1, and more preferably 4:2 to 2:1.

When the inorganic particles are used as the particles, the anti-glare layer preferably contains inorganic fine particles, described later, in order to easily set AM1 and AM2 within the above range.

The average particle size D of particles such as organic particles and inorganic particles is preferably 1.0 μm or more and 10.0 μm or less, more preferably 1.5 μm or more and 8.0 μm or less, and still more preferably 1.7 μm or more and 6.0 μm or less.

By setting the average particle size D to 1.0 μm or more, AM1 and Rq can be easily increased. Among the particles, the irregularly shaped inorganic particles easily increase AM1, Δq, and λq. By setting the average particle size D to 10.0 μm or less, AM2 and λq can be easily set to be small, and AM1, Δq, and Rq can be easily suppressed from becoming too small.

Embodiments of a preferable range of the average particle size of the particles include 1.0 μm or more and 10.0 μm or less, 1.0 μm or more and 8.0 μm or less, 1.0 μm or more and 6.0 μm or less, 1.5 μm or more and 10.0 μm or less, 1.5 μm or more and 8.0 μm or less, 1.5 μm or more and 6.0 μm or less, 1.7 μm or more and 10.0 μm or less, 1.7 μm or more and 8.0 μm or less, and 1.7 μm or more and 6.0 μm or less.

The average particle size of particles such as organic particles and inorganic particles can be calculated by the following operations (A1) to (A3).
(A1) A transmission observation image of the anti-glare film is imaged with an optical microscope. The magnification is preferably 500 times or more and 2000 times or less.
(A2) Any 10 particles are extracted from the observed image and the particle size of each particle is calculated. The particle size is measured as the linear distance in a combination of two straight lines such that the linear distance between the two straight lines is maximum when the cross-section of the particle is sandwiched between two arbitrary parallel straight lines.
(A3) The same operation is performed five times on an observation image of another screen of the same sample, and a value obtained from the number average of the particle size of 50 particles in total is defined as the average particle size of the particles.

The ratio D/T of the thickness T of the anti-glare layer and the average particle size D of the particles is preferably 0.20 or more and 0.96 or less, more preferably 0.25 or more and 0.90 or less, still more preferably 0.30 or more and 0.80 or less, and further preferably 0.35 or more and 0.70 or less. By setting D/T within the above range, it is possible to easily set the height of the peaks and the interval between the peaks of the uneven surface to be in an appropriate range, and to easily set AM1, AM2, Δq, λq, and Rq to be in the range described above. By setting D/T to 0.96 or less, AM1 and Rq can be easily suppressed from becoming too large.

Examples of the preferred range of D/T include 0.20 or more and 0.96 or less, 0.20 or more and 0.90 or less, 0.20 or more and 0.80 or less, 0.20 or more and 0.70 or less, 0.25 or more and 0.96 or less, 0.25 or more and 0.90 or less, 0.25 or more and 0.80 or less, 0.25 or more and 0.70 or less, 0.30 or more and 0.96 or less, 0.30 or more and 0.90 or less, 0.30 or more and 0.80 or less, 0.30 or more and 0.70 or less, 0.35 or more and 0.96 or less, 0.35 or more and 0.90 or less, 0.35 or more and 0.80 or less, and 0.35 or more and 0.70 or less.

The content of particles such as organic particles and inorganic particles is preferably 10 parts by mass or more and 200 parts by mass or less, more preferably 15 parts by mass or more and 170 parts by mass or less, and still more preferably 20 parts by mass or more and 150 parts by mass or less based on 100 parts by mass of the binder resin.

By setting the content of the particles to 10 parts by mass or more, AM1, AM2, Δq, and Rq can be easily set to be large, and λq is easily set to be small. By setting the content of the particles to 200 parts by mass or less, AM1 and AM2 can be easily suppressed from becoming too large, and the particles can be easily suppressed from falling off from the anti-glare layer.

When the organic particles are used and the irregularly shaped inorganic particles are not used as the particles, the content of the particles is preferably set to a relatively large amount in the above range in order to easily exhibit “particle spreading” and “particle stacking”. When the irregularly shaped inorganic particles are used as the particles, the content of the particles is preferably set to a relatively small amount in the above range in order to suppress AM1 from becoming too large.

Embodiments of a preferable range of the content of the particles with respect to 100 parts by mass of the binder resin include 10 parts by mass or more and 200 parts by mass or less, 10 parts by mass or more and 170 parts by mass or less, 10 parts by mass or more and 150 parts by mass or less, 15 parts by mass or more and 200 parts by mass or less, 15 parts by mass or more and 170 parts by mass or less, 15 parts by mass or more and 150 parts by mass or less, 20 parts by mass or more and 200 parts by mass or less, 20 parts by mass or more and 170 parts by mass or less, and 20 parts by mass or more and 150 parts by mass or less.

### —Inorganic Fine Particles—

The anti-glare layer preferably further contains inorganic fine particles in addition to the binder resin and the particles. In the present specification, the inorganic fine particles and the aforementioned particles can be distinguished with the average particle size.

When the anti-glare layer contains the inorganic fine particles, since a viscosity of an anti-glare layer-coating liquid can be increased, the particles are less likely to sink. Further, when the anti-glare layer contains the inorganic fine particles, fine unevenness is easily formed between peaks of the uneven surface. Thus, when the anti-glare layer contains the inorganic fine particles, AM1, AM2, Δq, λq, and Rq are easily set within the aforementioned ranges. When the anti-glare layer contains the inorganic fine particles, the particles are preferably the organic particles.

The inorganic fine particles contained in the anti-glare layer reduces the difference between the refractive index of the particles and the refractive index of the composition other than the particles of the anti-glare layer, and the internal haze can be easily reduced.

Examples of the inorganic fine particles include fine particles made of silica, alumina, zirconia, and titania. Among these, silica is preferable since it easily suppresses the generation of internal haze.

The average particle size of the inorganic fine particles is preferably 1 nm or more and 200 nm or less, more preferably 2 nm or more and 100 nm or less, and still more preferably 5 nm or more and 50 nm or less.

Examples of the preferred range of the average particle size of the inorganic fine particles include 1 nm or more and 200 nm or less, 1 nm or more and 100 nm or less, 1 nm or more and 50 nm or less, 2 nm or more and 200 nm or less, 2 nm or more and 100 nm or less, 2 nm or more and 50 nm or less, 5 nm or more and 200 nm or less, 5 nm or more and 100 nm or less, and 5 nm or more and 50 nm or less.

The average particle size of the inorganic fine particles can be calculated by the following operations (B1) to (B3).
(B1) A cross-section of the anti-glare film is imaged with a TEM or STEM. The acceleration voltage of the TEM or STEM is preferably 10 kV or more and 30 kV or less, and the magnification is preferably 50,000 times or more and 300,000 times or less.
(B2) Any 10 inorganic fine particles are extracted from the observed image and the particle size of each inorganic fine particle is calculated. The particle size is measured as the linear distance in a combination of two straight lines such that the linear distance between the two straight lines is maximum when the cross-section of the inorganic fine particle is sandwiched between two arbitrary parallel straight lines.
(B3) The same operation is performed five times on an observation image of another screen of the same sample, and a value obtained from the number average of the particle size of 50 particles in total is defined as the average particle size of the inorganic fine particles.

The content of inorganic fine particles is preferably 10 parts by mass or more and 200 parts by mass or less, more preferably 15 parts by mass or more and 150 parts by mass or less, and still more preferably 20 parts by mass or more and 80 parts by mass or less based on 100 parts by mass of the binder resin.

By setting the content of the inorganic fine particles to 10 parts by mass or more, the aforementioned effect based on the inorganic fine particles can be easily obtained. By setting the content of the inorganic fine particles to 200 parts by mass or less, a decrease in coating film strength of the anti-glare layer can be easily suppressed, and prevention of flowability of the particles is suppressed, and AM1 and AM2 are easily set within the aforementioned ranges.

Embodiments of a preferable range of the content of the inorganic fine particles with respect to 100 parts by mass of the binder resin include 10 parts by mass or more and 200 parts by mass or less, 10 parts by mass or more and 150 parts by mass or less, 10 parts by mass or more and 80 parts by mass or less, 15 parts by mass or more and 200 parts by mass or less, 15 parts by mass or more and 150 parts by mass or less, 15 parts by mass or more and 80 parts by mass or less, 20 parts by mass or more and 200 parts by mass or less, 20 parts by mass or more and 150 parts by mass or less, and 20 parts by mass or more and 80 parts by mass or less.

### —Binder Resin—

In order to further improve the mechanical strength, the binder resin preferably contains a cured product of a curable resin such as a cured product of a thermosetting resin composition or a cured product of an ionizing radiation-curable resin composition, and more preferably contains a cured product of an ionizing radiation-curable resin composition.

The thermosetting resin composition is a composition containing at least a thermosetting resin, and is a resin composition that is cured by heating.

Examples of thermosetting resins include acrylic resins, urethane resins, phenol resins, urea melamine resins, epoxy resins, unsaturated polyester resins, and silicone resins. If necessary, a curing agent is added to these curable resins in the thermosetting resin composition.

The ionizing radiation-curable resin composition is a composition containing a compound having an ionizing radiation-curable functional group (hereinafter also referred to as an “ionizing radiation-curable compound”). Examples of the ionizing radiation-curable functional group include ethylenically unsaturated bond groups such as a (meth)acryloyl group, a vinyl group, and an allyl group; an epoxy group; and an oxetanyl group. The ionizing radiation-curable compound is preferably a compound having an ethylenically unsaturated bond group, more preferably a compound having two or more ethylenically unsaturated bond groups, and in particular, still more preferably a polyfunctional (meth)acrylate-based compound having two or more ethylenically unsaturated bond groups. Both monomers and oligomers can be used as polyfunctional (meth)acrylate-based compounds.

The ionizing radiation means an electromagnetic wave or a charged particle beam having an energy quantum capable of polymerizing or crosslinking a molecule, and an ultraviolet ray (UV) or an electron beam (EB) is usually used, but an electromagnetic wave such as an X-ray or a γ-ray, or a charged particle beam such as an α-ray or an ion beam can also be used.

Among the polyfunctional (meth)acrylate-based compounds, examples of the bifunctional (meth)acrylate-based monomer include ethylene glycol di(meth)acrylate, bisphenol A tetraethoxy diacrylate, bisphenol A tetrapropoxy diacrylate, and 1,6-hexanediol diacrylate.

Examples of the (meth)acrylate-based monomer having three or more functional groups include trimethylolpropane tri(meth)acrylate, pentaerythritol tri(meth)acrylate, pentaerythritol tetra(meth)acrylate, dipentaerythritol hexa(meth)acrylate, dipentaerythritol tetra(meth)acrylate, and isocyanuric acid-modified tri(meth)acrylate.

The (meth)acrylate-based monomer may be a monomer in which a part of the molecular skeleton is modified. For example, a monomer in which a part of the molecular skeleton is modified with ethylene oxide, propylene oxide, caprolactone, isocyanuric acid, alkyl, cyclic alkyl, aromatic, bisphenol, or the like can also be used as the (meth)acrylate-based monomer.

Examples of polyfunctional (meth)acrylate-based oligomers include acrylate-based polymers such as urethane (meth)acrylate, epoxy (meth)acrylate, polyester (meth)acrylate, and polyether (meth)acrylate.

Urethane (meth)acrylate is obtained, for example, by reacting polyhydric alcohol and organic diisocyanate with hydroxy (meth)acrylate.

Preferred epoxy (meth)acrylates are (meth)acrylates obtained by reacting a trifunctional or more aromatic epoxy resin, alicyclic epoxy resin, or aliphatic epoxy resin with a (meth)acrylic acid, (meth)acrylates obtained by reacting a bifunctional or more aromatic epoxy resin, alicyclic epoxy resin, or aliphatic epoxy resin with a polybasic acid and (meth)acrylic acid, and (meth)acrylates obtained by reacting a bifunctional or more aromatic epoxy resin, alicyclic epoxy resin, or aliphatic epoxy resin with phenol and (meth)acrylic acid.

For the purpose of adjusting the viscosity of the anti-glare layer-coating liquid or the like, a monofunctional (meth)acrylate may be used in combination as the ionizing radiation-curable compound. Examples of the monofunctional (meth)acrylate include methyl (meth)acrylate, ethyl (meth)acrylate, propyl (meth)acrylate, butyl (meth)acrylate, pentyl (meth)acrylate, hexyl (meth)acrylate, cyclohexyl (meth)acrylate, 2-ethylhexyl (meth)acrylate, lauryl (meth)acrylate, stearyl (meth)acrylate, and isobornyl (meth)acrylate.

The ionizing radiation-curable compounds may be used singly or in combination of two or more.

When the ionizing radiation-curable compound is an ultraviolet-curable compound, the ionizing radiation-curable composition preferably contains an additive such as a photopolymerization initiator or a photopolymerization accelerator.

Examples of the photopolymerization initiator include one or more selected from the group consisting of acetophenone, benzophenone, α-hydroxyalkylphenone, Michler's ketone, benzoin, benzyl dimethyl ketal, benzoyl benzoate, α-acyloxime ester, thioxanthones, and the like.

The photopolymerization accelerator can reduce polymerization inhibition caused by air during curing and increase the curing rate. Examples of the accelerator include p-dimethylaminobenzoic acid isoamyl ester, p-dimethylaminobenzoic acid ethyl ester, and the like.

When the binder resin contains a cured product of an ionizing radiation-curable resin composition, the binder resin preferably has a configuration (C1) or (C2) as described below.
(C1) A thermoplastic resin is contained as the binder resin in addition to the cured product of the ionizing radiation-curable resin composition.
(C2) Substantially only the cured product of the ionizing radiation-curable resin composition is contained as the binder resin, and 70% by mass or more of a monomer component is contained as the ionizing radiation-curable compound contained in the ionizing radiation-curable resin composition.

In the embodiment C1 described above, the viscosity of the anti-glare layer-coating liquid is increased by the thermoplastic resin, so that the particles are less likely to sink, and the binder resin is less likely to flow down between the peaks. Therefore, in the embodiment C1 above, it is possible to easily set AM1, AM2, and Δq to be large, and easily set λq to be small. In the embodiment C1 above, a case where the anti-glare layer contains the inorganic fine particles is preferable because the viscosity of the anti-glare layer-coating liquid can be more increased by the inorganic fine particles. In the embodiment C1 above, the organic particles are preferably used as the particles, and the inorganic fine particles are preferably contained.

Examples of the thermoplastic resin include polystyrene-based resins, polyolefin-based resins, ABS resins (including heat-resistant ABS resins), AS resins, AN resins, polyphenylene oxide-based resins, polycarbonate-based resins, polyacetal-based resins, acrylic resins, polyethylene terephthalate-based resins, polybutylene terephthalate-based resins, polysulfone-based resins, and polyphenylene sulfide-based resins, and acrylic resin is preferable to improve transparency.

The weight-average molecular weight of the thermoplastic resin is preferably 20,000 or more and 200,000 or less, more preferably 30,000 or more and 150,000 or less, and still more preferably 50,000 or more and 100,000 or less.

In the present specification, the weight-average molecular weight is the average molecular weight measured by GPC analysis and converted to standard polystyrene.

Examples of the preferred range of the weight-average molecular weight of the thermoplastic resin include 20,000 or more and 200,000 or less, 20,000 or more and 150,000 or less, 20,000 or more and 100,000 or less, 30,000 or more and 200,000 or less, 30,000 or more and 150,000 or less, 30,000 or more and 100,000 or less, 50,000 or more and 200,000 or less, 50,000 or more and 150,000 or less, and 50,000 or more and 100,000 or less.

In the embodiment C1 above, the mass ratio of the cured product of the ionizing radiation-curable resin composition and the thermoplastic resin is preferably 60:40 to 90:10, and more preferably 70:30 to 80:20.

By setting the thermoplastic resin to 10 or more with respect to the cured product 90 of the ionizing radiation-curable resin composition, the effect of increasing the viscosity of the anti-glare layer-coating liquid described above can be easily exhibited. By setting the thermoplastic resin to 40 or less with respect to the cured product 60 of the ionizing radiation-curable resin composition, the decrease in the mechanical strength of the anti-glare layer can be easily suppressed.

In the embodiment C2 above, the particles are spread all over the bottom portion of the anti-glare layer, and the particles are stacked in a part of the region, and these particles tend to be covered with a thin-skinned binder resin. Thus, in the embodiment C2 above, AM1 and Δq can be easily set to be large by the stacked particles, and AM2 and λq can be easily set to be small by the spread particles. In the embodiment C2 above, the particles are preferably the inorganic particles, more preferably the irregularly shaped inorganic particles, and further preferably irregularly shaped silica. In the embodiment C2 above, the organic particles are preferably contained in addition to the inorganic particles.

In the C2 above, the ratio of the cured product of the ionizing radiation-curable resin composition to the total amount of the binder resin is preferably 90% by mass or more, more preferably 95% by mass or more, and still more preferably 100% by mass.

In the C2 above, the ratio of the monomer component to the total amount of the ionizing radiation-curable compound is preferably 90% by mass or more, more preferably 95% by mass or more, and still more preferably 100% by mass. The monomer component is preferably a polyfunctional (meth)acrylate-based compound.

A solvent is preferably contained in the anti-glare layer-coating liquid to adjust the viscosity and to dissolve or disperse each component. Since the surface shape of the anti-glare layer after coating and drying differs depending on the type of solvent, it is preferable to select the solvent in consideration of the saturated vapor pressure of the solvent, the permeability of the solvent to the transparent substrate, and the like.

Examples of the solvent include ketones such as acetone, methyl ethyl ketone, methyl isobutyl ketone, and cyclohexanone; ethers such as dioxane and tetrahydrofuran; aliphatic hydrocarbons such as hexane; alicyclic hydrocarbons such as cyclohexane; aromatic hydrocarbons such as toluene and xylene; halogenated carbons such as dichloromethane and dichloroethane; esters such as methyl acetate, ethyl acetate, and butyl acetate; alcohols such as isopropanol, butanol, and cyclohexanol; cellosolves such as methyl cellosolve and ethyl cellosolve; glycol ethers such as propylene glycol monomethyl ether acetate; cellosolve acetates; sulfoxides such as dimethyl sulfoxide; amides such as dimethylformamide and dimethylacetamide; and a mixture of these.

It is preferable that the main component of the solvent in the anti-glare layer-coating liquid is a solvent having a high evaporation rate. By increasing the evaporation rate of the solvent, the particles are prevented from settling to the bottom portion of the anti-glare layer, and the binder resin is less likely to flow down between the peaks. Therefore, AM1, AM2, and Δq can be easily set to be large, and λq can be easily set to be small.

The main component means 50% by mass or more, preferably 70% by mass or more, and more preferably 80% by mass or more of the total amount of the solvent.

In the present specification, a solvent having a high evaporation rate means a solvent having an evaporation rate of 100 or more when the evaporation rate of butyl acetate is 100. The evaporation rate of the solvent having a high evaporation rate is more preferably 120 or more and 300 or less, still more preferably 150 or more and 220 or less.

Examples of solvents having a high evaporation rate include methyl isobutyl ketone having an evaporation rate of 160, toluene having an evaporation rate of 200, and methyl ethyl ketone having an evaporation rate of 370.

The solvent in the anti-glare layer-coating liquid preferably also contains a small amount of solvent having a low evaporation rate in addition to the solvent having a high evaporation rate. By containing a small amount of a solvent having a low evaporation rate, the particles are agglomerated, and AM1, Δq, and Rq can be easily set to be large. Note that, in order to suppress AM1 and Rq from becoming too large, it is important that a content of the solvent having a low evaporation rate is set to be small.

The mass ratio of the solvent having a high evaporation rate and the solvent having a low evaporation rate is preferably 99:1 to 80:20, more preferably 98:2 to 85:15.

In the present specification, a solvent having a low evaporation rate means a solvent having an evaporation rate of less than 100 when the evaporation rate of butyl acetate is 100. The evaporation rate of the solvent having a low evaporation rate is more preferably 20 or more and 60 or less, and still more preferably 25 or more and 40 or less.

Examples of solvents having a low evaporation rate include cyclohexanone having an evaporation rate of 32 and propylene glycol monomethyl ether acetate having an evaporation rate of 44.

It is preferable to control the drying conditions when forming the anti-glare layer from the anti-glare layer-coating liquid.

The drying conditions can be controlled by the drying temperature and the wind speed inside the dryer. The drying temperature is preferably 30° C. or more and 120° C. or less, and the drying wind speed is preferably 0.2 m/s or more and 50 m/s or less. In order to control the surface shape of the anti-glare layer by drying, the irradiation with ionizing-radiation is preferably performed after the drying of the coating liquid.

### <Optical Characteristics>

The anti-glare film preferably has a total light transmittance in accordance with JIS K7361-1:1997 of 70% or more, more preferably 80% or more, and still more preferably 85% or more.

The light incident surface for measuring total light transmittance and haze, which will be described later, is the opposite side of the uneven surface.

The anti-glare film preferably has a haze in accordance with JIS K7136:2000 of 40% or more and 98% or less, more preferably 50% or more and 80% or less, and further preferably 55% or more and 70% or less.

By setting the haze to 40% or more, the anti-glare properties can be better. By setting the haze to 98% or less, the deterioration in image resolution can be easily suppressed.

Examples of the preferred range of the haze include 40% or more and 98% or less, 40% or more and 80% or less, 40% or more and 70% or less, 50% or more and 98% or less, 50% or more and 80% or less, 50% or more and 70% or less, 55% or more and 98% or less, 55% or more and 80% or less, and 55% or more and 70% or less.

The anti-glare film preferably has an internal haze of 20% or less, more preferably 15% or less, and still more preferably 10% or less in order to facilitate better image resolution and contrast.

Internal haze can be measured by a general-purpose method, for example, and can be measured by laminating a transparent sheet on the uneven surface via a transparent adhesive layer to flatten the unevenness of the uneven surface.

As for a transmitted image clearness of the anti-glare film measured in accordance with JIS K7374:2007, when a transmitted image clearness with a width of an optical comb of 0.125 mm is defined as C_{0.125}, a transmitted image clearness with a width of an optical comb of 0.25 mm is defined as C_{0.25}, a transmitted image clearness with a width of an optical comb of 0.5 mm is defined as C_{0.5}, a transmitted image clearness with a width of an optical comb of 1.0 mm is defined as C_{1.0}, and a transmitted image clearness with a width of an optical comb of 2.0 mm is defined as C_{2.0}, values of C_{0.125}, C_{0.25}, C_{0.5}, C_{1.0}, and C_{2.0} are preferably within the following ranges.

To improve the anti-glare properties, C_{0.125} is preferably 50% or less, more preferably 40% or less, more preferably 30% or less, and more preferably 20% or less. To improve the resolution, C_{0.125} is preferably 1.0% or more. Examples of the range of C_{0.125} include 1.0% or more and 50% or less, 1.0% or more and 40% or less, 1.0% or more and 30% or less, and 1.0% or more and 20% or less.

To improve the anti-glare properties, C_{0.25} is preferably 50% or less, more preferably 40% or less, more preferably 30% or less, and more preferably 20% or less. To improve the resolution, C_{0.25} is preferably 1.0% or more. Examples of the range of C_{0.25} include 1.0% or more and 50% or less, 1.0% or more and 40% or less, 1.0% or more and 30% or less, and 1.0% or more and 20% or less.

To improve the anti-glare properties, C_{0.5} is preferably 50% or less, more preferably 40% or less, more preferably 30% or less, and more preferably 20% or less. To improve the resolution, C_{0.5} is preferably 1.0% or more. Examples of the range of C_{0.5} include 1.0% or more and 50% or less, 1.0% or more and 40% or less, 1.0% or more and 30% or less, and 1.0% or more and 20% or less.

To improve the anti-glare properties, C_{1.0} is preferably 50% or less, more preferably 40% or less, more preferably 30% or less, and more preferably 20% or less. To improve the resolution, C_{1.0} is preferably 1.0% or more. Examples of the range of C_{1.0} include 1.0% or more and 50% or less, 1.0% or more and 40% or less, 1.0% or more and 30% or less, and 1.0% or more and 20% or less.

To improve the anti-glare properties, C_{2.0} is preferably 50% or less, more preferably 40% or less, more preferably 30% or less, and more preferably 25% or less. To improve the resolution, C_{2.0} is preferably 5.0% or more. Examples of the range of C_{2.0} include 5.0% or more and 50% or less, 5.0% or more and 40% or less, 5.0% or more and 30% or less, and 5.0% or more and 25% or less.

To improve the anti-glare properties of the anti-glare film, a total of C_{0.125}, C_{0.5}, C_{1.0}, and C_{2.0} is preferably 200% or less, more preferably 150% or less, more preferably 100% or less, and more preferably 80% or less. To improve the resolution, the total is preferably 10.0% or more. Examples of a range of the total include 10.0% or more and 200% or less, 10.0% or more and 150% or less, 10.0% or more and 100% or less, and 10.0% or more and 80% or less.

To improve the anti-glare properties of the anti-glare film, a 20°-specular glossiness measured from the uneven surface side is preferably 6.0 or less, more preferably 3.0 or less, further preferably 1.0 or less, and still further preferably 0.5 or less.

When the 20°-specular glossiness of the anti-glare film is too low, the video light tends to be scattered in transmitting the anti-glare film, and the dark-room contrast tends to decrease. Thus, the 20°-specular glossiness of the anti-glare film is preferably 0.01 or more, more preferably 0.02 or more, and further preferably 0.04 or more.

Examples of a preferable range of 20°-specular glossiness of the anti-glare film include 0.01 or more and 6.0 or less, 0.01 or more and 3.0 or less, 0.01 or more and 1.0 or less, 0.01 or more and 0.5 or less, 0.02 or more and 6.0 or less, 0.02 or more and 3.0 or less, 0.02 or more and 1.0 or less, 0.02 or more and 0.5 or less, 0.04 or more and 6.0 or less, 0.04 or more and 3.0 or less, 0.04 or more and 1.0 or less, and 0.04 or more and 0.5 or less.

### <Other Layers>

The anti-glare film may have another layer which is a layer other than the anti-glare layer and transparent substrate described above. Examples of the other layers include an anti-reflection layer, an anti-fouling layer, and an anti-static layer.

Examples of a preferred embodiment in which another layer is provided include an embodiment in which an anti-reflection layer is provided on the uneven surface of the anti-glare layer and a surface of the anti-reflection layer is the uneven surface. The anti-reflection layer more preferably has antifouling properties. That is, it is more preferable that the antifouling anti-reflection layer is provided on the anti-glare layer and the surface of the antifouling anti-reflection layer is the uneven surface.

### <<Anti-Reflection Layer>>

The anti-reflection layer may have a single-layer structure of a low refractive index layer; a two-layer structure of a high refractive index layer and a low refractive index layer; or a multilayer structure of three or more layers, for example. The low refractive index layer and the high refractive index layer can be formed by a general-purpose wet method, dry method, or the like. The single-layer structure or two-layer structure is preferred in the case of the wet method, and the multi-layer structure is preferred in the case of the dry method.

### —Single-Layer Structure or Two-Layer Structure—

A single-layer structure or a two-layer structure is preferably formed by a wet method.

The low refractive index layer is preferably disposed on the outermost surface of the anti-glare film. When imparting antifouling properties to the anti-reflection layer, the low refractive index layer preferably contains an antifouling agent such as a silicone-based compound and a fluorine-based compound.

The lower limit of the refractive index of the low refractive index layer is preferably 1.10 or more, more preferably 1.20 or more, more preferably 1.26 or more, more preferably 1.28 or more, and more preferably 1.30 or more, and the upper limit thereof is preferably 1.48 or less, more preferably 1.45 or less, more preferably 1.40 or less, more preferably 1.38 or less, and more preferably 1.32 or less.

Examples of the preferred range of the refractive index of the low refractive index layer include 1.10 or more and 1.48 or less, 1.10 or more and 1.45 or less, 1.10 or more and 1.40 or less, 1.10 or more and 1.38 or less, 1.10 or more and 1.32 or less, 1.20 or more and 1.48 or less, 1.20 or more and 1.45 or less, 1.20 or more and 1.40 or less, 1.20 or more and 1.38 or less, 1.20 or more and 1.32 or less, 1.26 or more and 1.48 or less, 1.26 or more and 1.45 or less, 1.26 or more and 1.40 or less, 1.26 or more and 1.38 or less, 1.26 or more and 1.32 or less, 1.28 or more and 1.48 or less, 1.28 or more and 1.45 or less, 1.28 or more and 1.40 or less, 1.28 or more and 1.38 or less, 1.28 or more and 1.32 or less, 1.30 or more and 1.48 or less, 1.30 or more and 1.45 or less, 1.30 or more and 1.40 or less, 1.30 or more and 1.38 or less, and 1.30 or more and 1.32 or less.

The lower limit of the thickness of the low refractive index layer is preferably 80 nm or more, more preferably 85 nm or more, more preferably 90 nm or more, and the upper limit thereof is preferably 150 nm or less, more preferably 110 nm or less, and more preferably 105 nm or less.

Examples of the preferred range of the thickness of the low refractive index layer include 80 nm or more and 150 nm or less, 80 nm or more and 110 nm or less, 80 nm or more and 105 nm or less, 85 nm or more and 150 nm or less, 85 nm or more and 110 nm or less, 85 nm or more and 105 nm or less, 90 nm or more and 150 nm or less, 90 nm or more and 110 nm or less, and 90 nm or more and 105 nm or less.

The high refractive index layer is preferably disposed closer to the anti-glare layer than the low refractive index layer.

The lower limit of the refractive index of the high refractive index layer is preferably 1.53 or more, more preferably 1.54 or more, more preferably 1.55 or more, more preferably 1.56 or more, and the upper limit thereof is preferably 1.85 or less, more preferably 1.80 or less, more preferably 1.75 or less, and more preferably 1.70 or less.

Examples of the preferred range of the refractive index of the high refractive index layer include 1.53 or more and 1.85 or less, 1.53 or more and 1.80 or less, 1.53 or more and 1.75 or less, 1.53 or more and 1.70 or less, 1.54 or more and 1.85 or less, 1.54 or more and 1.80 or less, 1.54 or more and 1.75 or less, 1.54 or more and 1.70 or less, 1.55 or more and 1.85 or less, 1.55 or more and 1.80 or less, 1.55 or more and 1.75 or less, 1.55 or more and 1.70 or less, 1.56 or more and 1.85 or less, 1.56 or more and 1.80 or less, 1.56 or more and 1.75 or less, and 1.56 or more and 1.70 or less.

The upper limit of the thickness of the high refractive index layer is preferably 200 nm or less, more preferably 180 nm or less, still more preferably 150 nm or less, and the lower limit is preferably 50 nm or more, and more preferably 70 nm or more.

Examples of the preferred range of the thickness of the high refractive index layer include 50 nm or more and 200 nm or less, 50 nm or more and 180 nm or less, 50 nm or more and 150 nm or less, 70 nm or more and 200 nm or less, 70 nm or more and 180 nm or less, and 70 nm or more and 150 nm or less.

### —Multilayer Structure of Three or More Layers—

The multilayer structure preferably formed by the dry method has a structure in which high refractive index layers and low refractive index layers are alternately laminated to form a total of three or more layers. Also in the multilayer structure, the low refractive index layer is preferably disposed on the outermost surface of the anti-glare film.

The high refractive index layer preferably has a thickness of 10 nm or more and 200 nm or less, and preferably has a refractive index of 2.10 or more and 2.40 or less. The thickness of the high refractive index layer is more preferably 20 nm or more and 70 nm or less.

The low refractive index layer preferably has a thickness of 5 nm or more and 200 nm or less, and preferably has a refractive index of 1.33 or more and 1.53 or less. The thickness of the low refractive index layer is more preferably 20 nm or more and 120 nm or less.

### <Size, Shape, and the Like>

The anti-glare film may be in the form of a sheet cut into a predetermined size, or may be in the form of a roll obtained by winding a long sheet. The size of the sheet is not particularly limited, but the maximum size is about 2 inches or more and 500 inches or less. The “maximum size” refers to the maximum length of any two points of the anti-glare film when connected. For example, when the anti-glare film is rectangular, the diagonal line of the rectangle is the maximum size. When the anti-glare film is circular, the diameter of the circle is the maximum size.

The width and length of the roll are not particularly limited, but generally, the width is 500 mm or more and 3000 mm or less and the length is about 500 m or more and 5000 m or less. The anti-glare film in the form of a roll may be cut into a sheet according to the size of an image display device or the like. At the time of cutting, it is preferable to exclude the end portion of the roll where the physical properties are not stable.

The shape of the sheet is not particularly limited, and examples thereof include polygons such as triangles, quadrilaterals, and pentagons, circles, and random irregular shapes. More specifically, when the anti-glare film has a square shape, the aspect ratio is not particularly limited as long as there is no problem as a display screen. For example, the aspect ratio may be horizontal:vertical=1:1, 4:3, 16:10, 16:9, 2:1, or the like, but the aspect ratio is not limited to such an aspect ratio in in-vehicle applications and digital signage which are rich in design.

The surface shape of the anti-glare film on the side opposite to the uneven surface is not particularly limited, but is preferably substantially smooth. Substantially smooth means that the arithmetic mean roughness Ra of JIS B0601:1994 at a cutoff value of 0.8 mm is less than 0.03 μm, preferably 0.02 μm or less.

### [Polarizing Plate]

The polarizing plate of the present disclosure is a polarizing plate comprising:

a polarizer;

a first transparent protective plate disposed on one side of the polarizer; and

a second transparent protective plate disposed on the other side of the polarizer, wherein

at least one of the first transparent protective plate and the second transparent protective plate is the aforementioned anti-glare film of the present disclosure, and

a surface opposite to the uneven surface of the anti-glare film and the polarizer are disposed so as to face each other.

### <Polarizer>

Examples of the polarizer include: sheet-type polarizers such as a polyvinyl alcohol film, a polyvinyl formal film, a polyvinyl acetal film, and an ethylene-vinyl acetate copolymer saponified film, which are dyed with iodine, etc., and stretched; wire-grid-type polarizers composed of many metal wires arranged in parallel; coated-type polarizers coated with a lyotropic liquid crystal or a dichromatic guest-host material; and multilayer thin-film-type polarizers. These polarizers may be reflective polarizers having a function of reflecting a polarized component not transmitted.

### <Transparent Protective Plate>

The first transparent protective plate is disposed on one side of the polarizer, and the second transparent protective plate is disposed on the other side. At least one of the first transparent protective plate and the second transparent protective plate is the aforementioned anti-glare film of the present disclosure.

The polarizing plate of the present disclosure may be a polarizing plate in which one of the first transparent protective plate and the second transparent protective plate is the aforementioned anti-glare film of the present disclosure, or may be a polarizing plate in which both the first transparent protective plate and the second transparent protective plate are the aforementioned anti-glare films of the present disclosure.

As the transparent protective plate other than the anti-glare film of the present disclosure among the first transparent protective plate and the second transparent protective plate, general-purpose plastic films and glass can be used.

The polarizer and the transparent protective plate are preferably laminated via an adhesive. A general-purpose adhesive can be used as the adhesive, and a PVA-based adhesive is preferred.

### [Surface Plate for Image Display Device]

A surface plate for an image display device of the present disclosure is a surface plate for an image display device, the surface plate comprising: a resin plate or a glass plate; and a protective film bonded to the resin plate or the glass plate, wherein the protective film is the aforementioned anti-glare film of the present disclosure, and a surface opposite to the uneven surface of the anti-glare film and the resin plate or the glass plate are disposed so as to face each other.

As the resin plate or the glass plate, resin plates or glass plates generally used as a surface plate of an image display device can be used.

To improve the strength, a thickness of the resin plate or the glass plate is preferably 10 μm or more. An upper limit of the thickness of the resin plate or the glass plate is typically 5000 μm or less. The upper limit of the thickness of the resin plate or the glass plate is preferably 1000 μm or less, more preferably 500 μm or less, and further preferably 100 μm or less for thinning.

Embodiments of a range of the thickness of the resin plate or the glass plate is 10 μm or more and 5000 μm or less, 10 μm or more and 1000 μm or less, 10 μm or more and 500 μm or less, and 10 μm or more and 100 μm or less.

### [Image Display Panel]

An image display panel of the present disclosure is an image display panel comprising: a display element; and an optical film disposed on a light-emitting surface side of the display element, wherein the image display panel comprises the aforementioned anti-glare film of the preset disclosure as the optical film, and the anti-glare film is disposed so that a surface of the anti-glare film on the uneven surface side is disposed so as to face the opposite side to the display element (see FIG. 3).

In the image display panel, the anti-glare film of the present disclosure is preferably disposed on an outermost surface on a light-emitting surface side of a display element.

Examples of display elements include liquid crystal display elements, EL display elements (organic EL display elements and inorganic EL display elements), plasma display elements, and LED display elements such as micro LED display elements. These display elements may have a touch panel function inside the display element.

Examples of the liquid crystal display method of the liquid crystal display element includes an IPS method, a VA method, a multi-domain method, an OCB method, an STN method, and a TSTN method.

The image display panel of the present disclosure may be an image display panel with a touch panel having the touch panel between the display element and the anti-glare film.

The size of the image display panel is not particularly limited, but the maximum size is about 2 inches or more and 500 inches or less. The maximum size refers to the maximum length of any two points within the surface of the image display panel.

### [Image Display Device]

The image display device of the present disclosure comprises the image display panel of the present disclosure.

The image display device of the present disclosure is not particularly limited as long as the image display device comprises the image display panel of the present disclosure. The image display device of the present disclosure preferably has: the image display panel of the present disclosure; a driving control part electrically connected to the image display panel; and a housing that houses these members.

When the display element is a liquid crystal display element, the image display device of the present disclosure requires a backlight. The backlight is disposed opposite to the light-emitting surface side of the liquid crystal display element.

The size of the image display device is not particularly limited, but the maximum size of the effective display region is about 2 inches or more and 500 inches or less.

The effective display region of an image display device is an area in which an image can be displayed. For example, when the image display device has a housing that surrounds the display element, the region inside the housing becomes the effective image region.

The maximum size of the effective image region refers to the maximum length of any two points within the effective image area when connected. For example, when the effective image region is rectangular, the diagonal line of the rectangle is the maximum size. When the effective image region is circular, the diameter of the circle is the maximum size.

### EXAMPLES

Next, the present disclosure will be described in more detail with reference to Examples, but the present disclosure is not limited by these Examples. “Parts” and “%” are based on mass unless otherwise specified.

### 1. Measurement and Evaluation

The anti-glare films of Examples and Comparative Examples were measured and evaluated as follows. The atmosphere during each measurement and evaluation was set at a temperature of 23±5° C., and a relative humidity of 40% or more and 65% or less. In addition, before starting each measurement and evaluation, the target sample was exposed to the atmosphere for 30 minutes or more and 60 minutes or less, and then the measurement and evaluation were performed. The results are shown in Table 1 or 2.

### 1-1. Measurement of AM1 and AM2

The anti-glare films of Examples and Comparative Examples were cut into pieces of 10 cm×10 cm. The cutting site was selected from random sites after visually confirming that there were no abnormal points such as dust and scratches. The transparent substrate side of the cut anti-glare film was bonded to a glass plate (thickness 2.0 cm) having a size of vertical 10 cm×horizontal 10 cm through an optically transparent adhesive sheet (trade name: Panaclean PD-S1, thickness 25 μm) manufactured by Panac Co., Ltd. to produce a sample 1.

Using a white light interferometry microscope (Zygo Corporation, New View7300), the sample 1 was set on a measurement stage so as to be fixed and in close contact with the measurement stage, and then the elevation of the uneven surfaces of the anti-glare film was measured and analyzed under the following measurement condition 1 and analysis condition 1 to calculate AM1 and AM2. Microscope Application of MetroPro ver 9.0.10 was used as measurement/analysis software.

### (Measurement Condition 1)

Objective lens: 50×

Image Zoom: lx

Measurement region: 218 μm×218 μm

Resolution (spacing per point): 0.22 μm
Instrument: NewView 7000 Id 0 SN 073395
Acquisition Mode: Scan
Scan Type: Bipolar
Camera Mode: 992×992 48 Hz
Subtract Sys Err: Off
SysErr File: SysErr. dat
AGC: Off
Phase Res: High
Connection Order: Location
Discon Action: Filter
Min Mod (%): 0.01
Min Area Size: 7
Remove Fringes: Off
Number of Averages: 0
FDA Noise Threshold: 10
Scan Length: 15 μm bipolar (6 sec)
Extended Scan Length: 1000 μm
FDA Res: High 2G

### (Analysis Condition 1)

Removed: None
Data Fill: On
Data Fill Max: 10000
Filter: High Pass
Filter Type: Gauss Spline
Filter Window Size: 3
Filter Trim: Off
Filter Low wavelength: 800 μm
Min Area Size: 0
Remove spikes: On
Spike Height (xRMS): 2.5
Low wavelength corresponds to the cutoff value kc in the roughness parameter.

### (Calculation Procedure for AM1 and AM2)

The “Save Data” button was displayed on the Surface Map screen, and the analyzed three-dimensional curved surface roughness data was saved in the “XYZ File (*.xyz)” format. Next, exporting was performed in Excel (Registered trademark) of Microsoft Corporation to obtain a two-dimensional function h(x,y) of elevation. A coordinate with a defect was exported as an elevation of the corresponding coordinate being zero. The number of obtained raw data was 992 rows in length×992 columns in width=984064 points, and the length of one side (MAx or NAy) was 218 μm, but by repeating deletion of the outer peripheral data 41 times, data of 910 rows in length×910 columns in width=828100 points, and in which the length of one side was 200 μm, was obtained. Next, using statistical analysis software R (ver 3.6.3), one-dimensional amplitude spectrum Hx′(fx) and Hy′(fy) of the elevation of each row and each column in the two-dimensional function of the elevation (910 rows in length×910 columns in width) were calculated, and the values of the amplitudes corresponding to the values of the respective spatial frequency were averaged to obtain a one-dimensional amplitude spectrum H″(f) of the elevation. The one-dimensional function H″(f) of the elevation was measured with respect to the surface at sixteen points for each sample, and the result of averaging the amplitude values corresponding to the respective spatial frequency values was the one-dimensional amplitude spectrum H(f) of elevation.

Then, from the obtained data, AM2 was extracted and AM1 was calculated. The values of the amplitude corresponding to the spatial frequency of 0.005 μm⁻¹, AM1-1, the amplitude corresponding to the spatial frequency of 0.010 μm⁻¹, AM1-2, and the amplitude corresponding to the spatial frequency of 0.015 μm⁻¹, AM1-3, are shown in Table 1.

FIGS. 6 to 16 show the discrete function H(f) of the amplitude spectrum of the elevation of the uneven surface of the anti-glare films of Examples 1 to 7 and Comparative Examples 1 to 4. In the figures, the horizontal axis represents the spatial frequency (unit: “μm⁻¹”), and the vertical axis represents the amplitude (unit: “μm”).

### 1-2. Total Light Transmittance (Tt) and Haze (Hz)

The anti-glare films of Examples and Comparative Examples were cut into pieces of 10 cm squares. The cutting site was selected from random sites after visually confirming that there were no abnormal points such as dust and scratches. The total light transmittance of JIS K7361-1:1997 and the haze of JIS K7136:2000 of each sample were measured using a haze meter (HM-150, manufactured by Murakami Color Research Laboratory Co., Ltd.). In order to stabilize the light source, the power switch of the apparatus was turned on in advance, and then the apparatus was allowed to stand for 15 minutes or more, and then, calibration was performed without setting anything in the inlet opening, and then a measurement sample was set in the inlet opening and measurement was performed. The light incident surface was on the side of the transparent substrate.

### 1-3. Anti-Glare Properties 1 (Anti-Glare Properties in Specular Reflection Direction)

The anti-glare films of Examples and Comparative Examples were cut into pieces of 10 cm×10 cm. The cutting site was selected from random sites after visually confirming that there were no abnormal points such as dust and scratches. The transparent substrate side of the cut anti-glare film was bonded to a black plate (Kuraray Co., Ltd., trade name: Comoglass DFA2CG 502K (black) Series, thickness 2 mm) having a size of vertical 10 cm×horizontal 10 cm through an optically transparent adhesive sheet (trade name: Panaclean PD-S1, thickness 25 μm) manufactured by Panac Co., Ltd. to produce a sample 2.

The sample 2 was placed on a horizontal table with a height of 70 cm so that the uneven surfaces faced upward, and reflection of illumination light on the uneven surfaces was evaluated in a bright room environment from an angle in the specular reflection direction of the illumination light according to the following evaluation criteria. During the evaluation, the position of the sample 2 with respect to the illumination was adjusted so that the incident angle of the light emitted from the center of the illumination with respect to the sample 2 was 10 degrees. A Hf32 type straight tube three-wavelength neutral white fluorescent lamp was used as illumination, and the position of the illumination was 2 m above the horizontal table in the vertical direction. The evaluation was carried out in a range where the illuminance on the uneven surface of the sample was 500 lux or more and 1000 lux or less. The position of the eyes of observer was about 160 cm from the floor. Observers were healthy people in their thirties with visual acuity of 0.7 or better.

### <Evaluation Criteria>

A: There is no outline of illumination, and position is not visible.
B: There is no outline of illumination, but position is vaguely visible.
C: Outline and position of illumination are vaguely visible.
D: Outline of illumination is less blurred, and position is clearly visible.

### 1-4. Anti-Glare Properties 2 (Anti-Glare Properties at Various Angles)

The sample 2 produced in 1-3 was held with both hands, and the reflection of the illumination light on the uneven surface was evaluated in the same manner as in 1-3 except that the evaluation was performed while changing the height and angle of the sample 2. The change of the angle described above was performed within a range in which the incident angle of the light emitted from the center of the illumination with respect to the sample 2 was 10 degrees or more and 70 degrees or less.

### 1-5. Reflected Scattered Light (≈Jet-Black Appearance)

The sample 2 prepared in 1-3 was placed on a horizontal table with a height of 70 cm with the uneven surface facing upward. The position of the sample 2 with respect to the illumination was adjusted so that the light having the strongest emission angle among the light emitted from the illumination did not just barely enter the sample 2. By the above-described adjustment, the position of the sample with respect to the observer is arranged on the side farther from the observer than the position of the sample 1-3.

Sample 2 was arranged at the position described above, and the degree of reflected scattered light was evaluated according to the following evaluation criteria. The line of sight of the observer was about 160 cm from the floor. Observers were 20 healthy people with visual acuity of 0.7 or better. For the 20 people, five people are selected from each age of twenties to fifties.

### <Evaluation Criteria>

A: Fourteen or more people felt good jet-black appearance.
B: Seven or more and thirteen or less people felt good jet-black appearance.
C: Six or less people felt good jet-black appearance.

### 1-6. Scratch Resistance

On the uneven surface of the anti-glare film of the sample 1 produced in 1-1, steel wool #0000 (available from Nippon Steel Wool Co., Ltd., trade name “Bonstar B-204”) was pressed with a predetermined load to perform a test of reciprocation ten times at a rate of 90 mm/s or more and 100 mm/s or less with a test length of 70 mm or more and 80 mm or less. An area where the load was applied was 1 cm×1 cm. On a surface opposite to the uneven surface of the sample 1 after the test, a black tape (available from YAMATO Co., LTD., trade name “YAMATO Vinyl Tape No. 200”) was laminated to produce a sample for scratch evaluation. From the uneven surface side of the sample for scratch evaluation, a scratch was visually observed under illumination with a three-wavelength fluorescent tube. An area of central 50 mm excluding the right and left edges in the test length of 70 mm or more and 80 mm or less was used as an effective region. A scratch generated in the effective region was evaluated according to the following criteria. A scratch with a length of 5 mm or more was counted, and a scratch with a length of less than 5 mm was not counted. Only the presence or absence of the scratch was evaluated, and a scratch mark was not included in the evaluation. The scratch was a linear mark with a width of less than 1 mm. A depth of the scratch was larger than a depth of the scratch mark. The scratch mark was a band-shaped thin mark with a width of about 1 cm observed within a range corresponding to a range scratched with steel wool.

### <Evaluation Criteria>

A: No scratch was observed at a pressing pressure with steel wool of 500 g/cm².
B: A scratch was observed at a pressing pressure with steel wool of g/cm², but no scratch was observed at a pressing pressure with steel wool of 300 g/cm².
C: A scratch was observed at a pressing pressure with steel wool of 300 g/cm².

### 1-7. Surface Shape Measurement

Using a white light interferometry microscope (Zygo Corporation, trade name “New View7300”), the sample produced in 1-1 was set on a measurement stage so as to be fixed and in close contact with the measurement stage, and then the surface shape of the anti-glare film was measured and analyzed under the following conditions. As a measurement software, trade name of Zygo Corporation “Microscope Stitching Application of MetroPro ver 9.0.10 (64-bit)” was used to perform measurement with automatically stitching a plurality of images. For analysis, Microscope Application of MetroPro ver 9.0.10 (64-bit) was used.

### (Measurement Condition)

Objective lens: 50×

### Image Zoom: 1×

### Stitch Controls

Type: Column & Row
N Cols: 3
N Rows: 3

### Overlap (%): 10

Measurement region: 611 μm×611 μm
Camera Res (resolution): 0.44 μm
Instrument: NewView 7000 Id 0 SN 073395
Acquisition Mode: Scan
Scan Lemgth: 10 μm bipolar (2 sec)
Camera Mode: 496×496 70 Hz
Subtract Sys Err: Off
SysErr File: SysErr. dat
AGC: Off
Phase Res: High
Connection Order: Location
Discon Action: Filter
Min Mod (%): 0.01
Min Area Size: 7
Remove Fringes: Off
Number of Averages: 0
FDA Noise Threshold: 10
Scan Length: 10 μm bipolar (3 sec)
Extended Scan Length: 1000 μm
FDA Res: High 2G

### (Analysis Condition)

Removed: None
Data Fill: On
Data Fill Max: 10000
Filter: High Pass
Filter Type: Gauss Spline
Filter Window Size: 3
Filter Trim: Off
Filter Low wavelength: 800 μm
Min Area Size: 0
Remove spikes: On
Spike Height (xRMS): 2.5

“Low wavelength” corresponds to “cutoff value λc” in the roughness parameter.

The “rms” was displayed on the Surface Map screen, and the value was specified as “Rq” of the measurement region. The “rms” was displayed on the Slope Mag Map screen, and the value was specified as “Δq” of the measurement region. The values of Rq and Δq were substituted for the formula (A) to calculate “λq”.

### 1-8. Transmitted Image Clearness

The anti-glare films of Examples and Comparative Examples were cut into pieces of 10 cm squares. The cutting site was selected from random sites after visually confirming that there were no abnormal points such as dust and scratches. The transmitted image clearness of the samples was measured by using an image clarity measuring device available from Suga Test Instruments Co., Ltd. (trade name: “ICM-iT”) in accordance with JIS K7374:2007. A width of an optical comb was five of 0.125 mm, 0.25 mm, 0.5 mm, 1.0 mm, or 2.0 mm. The light incident surface for the measurement was the transparent substrate side. The values of C_{0.125}, C_{0.25}, C_{0.5}, C_{1.0}, and C_{2.0} and the total value of C_{0.125}, C_{0.5}, C_{1.0}, and C_{2.0} were shown in Table 2 (Note: the total value was a value excluding C_{0.25}).

### 2. Production of Anti-Glare Film

### Example 1

An anti-glare layer-coating liquid 1 having the following formulation was applied onto a transparent substrate (triacetyl cellulose resin film (TAC) of 80 μm in thickness, Fujifilm Corporation, TD80 UL), dried at 70° C. and a wind velocity of 5 m/s for 30 seconds, and then irradiated with ultraviolet rays in a nitrogen gas atmosphere having an oxygen concentration of 200 ppm or less so that the integrated light quantity became 100 mJ/cm² to form an anti-glare layer, thereby obtaining an anti-glare film of Example 1. The thickness of the anti-glare layer was 5.0 μm. Ra on the side opposite to the anti-glare layer of the anti-glare film was 0.012 μm.

### <Anti-Glare Layer-Coating Liquid 1 (Coating Liquid for Example 1)>

Pentaerythritol triacrylate 80 parts
   (Nippon Kayaku Co., Ltd., trade name: KAYARAD-PET-30)
Urethane acrylate oligomer 20 parts
   (DIC Corporation, trade name: V-4000BA)
Silica particle 30 parts
   (average particle size: 4.1 μm)
   (available from FUJI SILYSIA CHEMICAL LTD., gel-method irregularly shaped silica)
Photopolymerization initiator 3 parts
   (IGM Resins B.V., trade name: Omnirad184)
Photopolymerization initiator 2 parts
   (IGM Resins B.V., trade name: Omnirad907)
Silicone leveling agent 0.2 parts
   (Momentive Performance Materials, trade name: TSF4460)
Solvent (toluene) 233.0 parts
Solvent (cyclohexanone) 27.1 parts

### [Examples 2, 5, and 6], [Comparative Examples 1 to 3]

Anti-glare films of Examples 2, 5, and 6 and Comparative Examples 1 to 3 were obtained in the same manner as in Example 1, except that anti-glare layer-coating liquid 1 was changed to the following anti-glare layer-coating liquids 2 and 5 to 9.

### [Examples 3 and 4], [Comparative Example 4]

Anti-glare films of Examples 3 and 4 and Comparative Example 4 were obtained in the same manner as in Example 1, except that anti-glare layer-coating liquid 1 was changed to the following anti-glare layer-coating liquids 3, 4, and 10, and the thickness of the anti-glare layer was changed to 6.5 μm.

### Example 7

On the anti-glare layer of the anti-glare film of the Example 3, a low refractive index layer-coating liquid 1 with the following formulation was applied, the coating was dried at 70° C. and a wind velocity of 5 m/s for 30 seconds, and then irradiated with ultraviolet rays in a nitrogen gas atmosphere (having an oxygen concentration of 200 ppm or less) so that the integrated light quantity became 100 mJ/cm² to form a low refractive index layer, thereby obtaining an anti-glare film of Example 7. The thickness of the low refractive index layer was 0.10 μm, and the refractive index was 1.32.

### <Anti-Glare Layer-Coating Liquid 2 (Coating Liquid for Example 2)>

Pentaerythritol triacrylate 51.4 parts
   (Nippon Kayaku Co., Ltd., trade name: KAYARAD-PET-30)
Urethane acrylate oligomer 23.7 parts
   (DIC Corporation, trade name: V-4000BA)
Thermoplastic resin 24.9 parts
   (Acryl polymer, MITSUBISHI RAYON CO., LTD., molecular weight 75,000)
Organic particles 43.3 parts
   (Sekisui Kasei Co., Ltd., spherical polyacrylic-styrene copolymer)
   (average particle size 2.5 μm, refractive index 1.515)
   (ratio of particles with a particle size of 2.3 to 2.7 μm is 90% or more)
Inorganic fine particle dispersion 182 parts
   (Nissan Chemical Industries, Ltd., silica having a reactive functional group introduced on its surface, solvent: MIBK, solid content: 35.5%)
   (average particle size 12 nm)
   (active ingredient of inorganic fine particles: 64.6 parts)
Photopolymerization initiator 1.5 parts
   (IGM Resins B.V., trade name: Omnirad184)
Photopolymerization initiator 4.8 parts
   (IGM Resins B.V., trade name: Omnirad907)
Silicone leveling agent 0.2 parts
   (Momentive Performance Materials, trade name: TSF4460)
Solvent (toluene) 317.6 parts
Solvent (cyclohexanone) 15.0 parts
Solvent (methyl isobutyl ketone) 121.1 parts

### <Anti-Glare Layer-Coating Liquid 3 (Coating Liquid for Examples 3 and 7)>

Pentaerythritol triacrylate 80 parts
   (Nippon Kayaku Co., Ltd., trade name: KAYARAD-PET-30)
Urethane acrylate oligomer 20 parts
   (DIC Corporation, trade name: V-4000BA)
Silica particle 20 parts
   (average particle size: 6.0 μm)
   (available from FUJI SILYSIA CHEMICAL LTD., gel-method irregularly shaped silica)
Organic particles 10 parts
   (Sekisui Kasei Co., Ltd., spherical polyacrylic-styrene copolymer)
   (average particle size 3.5 μm, refractive index 1.515)
   (ratio of particles with a particle size of 3.3 to 3.7 μm is 90% or more)
Photopolymerization initiator 3 parts
   (IGM Resins B.V., trade name: Omnirad184)
Photopolymerization initiator 2 parts
   (IGM Resins B.V., trade name: Omnirad907)
Silicone leveling agent 0.2 parts
   (Momentive Performance Materials, trade name: TSF4460)
Solvent (toluene) 233.0 parts
Solvent (cyclohexanone) 27.1 parts

### <Anti-Glare Layer-Coating Liquid 4 (Coating Liquid for Example 4)>

Pentaerythritol triacrylate 80 parts
   (Nippon Kayaku Co., Ltd., trade name: KAYARAD-PET-30)
Urethane acrylate oligomer 20 parts
   (DIC Corporation, trade name: V-4000BA)
Silica particle 27 parts
   (average particle size: 6.0 μm)
   (available from FUJI SILYSIA CHEMICAL LTD., gel-method irregularly shaped silica)
Organic particles 10 parts
   (Sekisui Kasei Co., Ltd., spherical polyacrylic-styrene copolymer)
   (average particle size 3.5 μm, refractive index 1.515)
   (ratio of particles with a particle size of 3.3 to 3.7 μm is 90% or more)
Photopolymerization initiator 3 parts
   (IGM Resins B.V., trade name: Omnirad184)
Photopolymerization initiator 2 parts
   (IGM Resins B.V., trade name: Omnirad907)
Silicone leveling agent 0.2 parts
   (Momentive Performance Materials, trade name: TSF4460)
Solvent (toluene) 233.0 parts
Solvent (cyclohexanone) 27.1 parts

### <Anti-Glare Layer-Coating Liquid 5 (Coating Liquid for Example 5)>

Pentaerythritol triacrylate 80 parts
   (Nippon Kayaku Co., Ltd., trade name: KAYARAD-PET-30)
Urethane acrylate oligomer 20 parts
   (DIC Corporation, trade name: V-4000BA)
Silica particle 60 parts
   (average particle size: 4.1 μm)
   (available from FUJI SILYSIA CHEMICAL LTD., gel-method irregularly shaped silica)
Photopolymerization initiator 3 parts
   (IGM Resins B.V., trade name: Omnirad184)
Photopolymerization initiator 2 parts
   (IGM Resins B.V., trade name: Omnirad907)
Silicone leveling agent 0.2 parts
   (Momentive Performance Materials, trade name: TSF4460)
Solvent (toluene) 233.0 parts
Solvent (cyclohexanone) 27.1 parts

### <Anti-Glare Layer-Coating Liquid 6 (Coating Liquid for Example 6)>

Pentaerythritol triacrylate 80 parts
   (Nippon Kayaku Co., Ltd., trade name: KAYARAD-PET-30)
Urethane acrylate oligomer 20 parts
   (DIC Corporation, trade name: V-4000BA)
Silica particle 20 parts
   (average particle size: 4.1 μm)
   (available from FUJI SILYSIA CHEMICAL LTD., gel-method irregularly shaped silica)
Organic particles 10 parts
   (Sekisui Kasei Co., Ltd., spherical polyacrylic-styrene copolymer)
   (average particle size 2.0 μm, refractive index 1.515)
   (ratio of particles with a particle size of 1.8 to 2.2 μm is 90% or more)
Photopolymerization initiator 3 parts
   (IGM Resins B.V., trade name: Omnirad184)
Photopolymerization initiator 2 parts
   (IGM Resins B.V., trade name: Omnirad907)
Silicone leveling agent 0.2 parts
   (Momentive Performance Materials, trade name: TSF4460)
Solvent (toluene) 233.0 parts
Solvent (cyclohexanone) 27.1 parts

### <Anti-Glare Layer-Coating Liquid 7 (Coating Liquid for Comparative Example 1)>

Pentaerythritol triacrylate 58.2 parts
   (Nippon Kayaku Co., Ltd., trade name: KAYARAD-PET-30)
Urethane acrylate oligomer 18.2 parts
   (DIC Corporation, trade name: V-4000BA)
Thermoplastic resin 23.6 parts
   (acrylic polymer, Mitsubishi Rayon Co., Ltd., molecular weight 75,000)
Organic particles 63.6 parts
   (Sekisui Plastics Co., Ltd., spherical polyacrylic-styrene copolymer)
   (average particle size 4.0 μm, refractive index 1.515)
   (ratio of particles with a particle size of 3.8 to 4.2 μm is 90% or more)
Inorganic fine particle dispersion 230 parts
   (Nissan Chemical Industries, Ltd., silica having a reactive functional group introduced on its surface, solvent: MIBK, solid content: 35.5%)
   (average particle size 12 nm)
   (active ingredient of inorganic fine particles: 81.9 parts)
Photopolymerization initiator 5.5 parts
   (IGM Resins B.V., trade name: Omnirad184)
Photopolymerization initiator 1.8 parts
   (IGM Resins B.V., trade name: Omnirad907)
Silicone leveling agent 0.2 parts
   (Momentive Performance Materials, trade name: TSF4460)
Solvent (toluene) 346.8 parts
Solvent (cyclohexanone) 17.9 parts

### <Anti-Glare Layer-Coating Liquid 8 (Coating Liquid for Comparative Example 2)>

Pentaerythritol triacrylate 100 parts
   (Nippon Kayaku Co., Ltd., trade name: KAYARAD-PET-30)
Silica particles 14 parts
   (average particle size: 4.1 μm)
   (manufactured by Fuji Silysia Chemical Ltd., gel method irregularly shaped silica)
Photopolymerization initiator 5 parts
   (IGM Resins B.V., trade name: Omnirad184)
Silicone leveling agent 0.2 parts
   (Momentive Performance Materials, trade name: TSF4460)
Solvent (toluene) 150 parts
Solvent (MIBK) 35 parts
Solvent (ethyl acetate) 5.2 parts

### <Anti-Glare Layer-Coating Liquid 9 (Coating Liquid for Comparative Example 3)>

Pentaerythritol triacrylate 100 parts
   (Nippon Kayaku Co., Ltd., trade name: KAYARAD-PET-30)
Organic particles 300.0 parts
   (Sekisui Kasei Co., Ltd., spherical polyacrylic-styrene copolymer)
   (average particle size 2.0 μm, refractive index 1.515)
   (ratio of particles with a particle size of 1.8 to 2.2 μm is 90% or more)
Photopolymerization initiator 6.4 parts
   (IGM Resins B.V., trade name: Omnirad184)
Photopolymerization initiator 1.0 parts
   (IGM Resins B.V., trade name: Omnirad907)
Silicone leveling agent 0.1 parts
   (Momentive Performance Materials, trade name: TSF4460)
Solvent (toluene) 498.4 parts
Solvent (cyclohexanone) 55.4 parts

### <Anti-Glare Layer-Coating Liquid 10 (Coating Liquid for Comparative Example 4)>

Pentaerythritol triacrylate 80 parts
   (Nippon Kayaku Co., Ltd., trade name: KAYARAD-PET-30)
Urethane acrylate oligomer 20 parts
   (DIC Corporation, trade name: V-4000BA)
Silica particle 30 parts
   (average particle size: 6.0 μm)
   (available from FUJI SILYSIA CHEMICAL LTD., gel-method irregularly shaped silica)
Organic particles 15 parts
   (Sekisui Kasei Co., Ltd., spherical polyacrylic-styrene copolymer)
   (average particle size 3.5 μm, refractive index 1.515)
   (ratio of particles with a particle size of 3.3 to 3.7 μm is 90% or more)
Photopolymerization initiator 3 parts
   (IGM Resins B.V., trade name: Omnirad184)
Photopolymerization initiator 2 parts
   (IGM Resins B.V., trade name: Omnirad907)
Silicone leveling agent 0.2 parts
   (Momentive Performance Materials, trade name: TSF4460)
Solvent (toluene) 233.0 parts
Solvent (cyclohexanone) 27.1 parts

### <Low Refractive Index Coating Liquid 1 (Coating Liquid for Example 7)>

Polyfunctional acrylate ester composition 100 parts by mass
   (available from DKS Co. Ltd., trade name “NEW FRONTIER MF-001”)
Hollow silica particles 200 parts by mass
   (average primary particle size 75 nm, particles surface-treated with a silane coupling agent having a methacryloyl group)
Solid silica particles 110 parts by mass
   (average primary particle size 12.5 nm, particles surface-treated with a silane coupling agent having a methacryloyl group)
Silicone leveling agent 13 parts by mass
   (Shin-Etsu Chemical Co., Ltd., trade name “X-22-164E”)
Photopolymerization initiator 4.3 parts by mass
   (IGM Resins B.V., trade name “Omnirad127”)
Solvent 14,867 parts by mass
   (mixed solvent of methyl isobutyl ketone and 1-methoxy-2-propyl acetate, mass ratio=68/32)

TABLE 1

| | | Presence/ | | | | | | |
|---|---|---|---|---|---|---|---|---|
| | Number of | absence | | | | | | |
| | anti-glare | of low | | | | | | |
| | layer-coating | refractive | AM1-1 | AM1-2 | AM1-3 | AM1_{AVE} | AM1 | AM2 |
| | liquid | index layer | [μm] | [μm] | [μm] | [μm] | [μm] | [μm] |
| Example 1 | 1 | absence | 0.1376 | 0.1364 | 0.1343 | 0.1361 | 0.4083 | 0.00964 |
| Example 2 | 2 | absence | 0.1607 | 0.2114 | 0.1560 | 0 1760 | 0.5280 | 0.00677 |
| Example 3 | 3 | absence | 0.2653 | 0.2038 | 0.2325 | 0.2339 | 0.7016 | 0.01376 |
| Example 4 | 4 | absence | 0.3813 | 0.2713 | 0.3245 | 0 3257 | 0.9770 | 0.01802 |
| Example 5 | 5 | absence | 0.2177 | 0.1837 | 0.2018 | 0.2027 | 0.6082 | 0.04419 |
| Example 6 | 6 | absence | 0.1415 | 0.1333 | 0.1349 | 0.1365 | 0.4096 | 0.00760 |
| Example 7 | 3 | presence | 0.2580 | 0.1954 | 0.2253 | 0.2263 | 0.6788 | 0.01334 |
| Comparative | 7 | absence | 0.1150 | 0.1198 | 0.1182 | 0.1177 | 0.3530 | 0.01016 |
| Example 1 | | | | | | | | |
| Comparative | 8 | absence | 0.1505 | 0.1259 | 0.1364 | 0.1376 | 0.4128 | 0.00284 |
| Example 2 | | | | | | | | |
| Comparative | 9 | absence | 0.1296 | 0.1442 | 0.1357 | 0.1365 | 0.4096 | 0.05829 |
| Example 3 | | | | | | | | |
| Comparative | 10 | absence | 0.3887 | 0.2855 | 0.3426 | 0.3389 | 1.0168 | 0.03610 |
| Example 4 | | | | | | | | |

| | | | | Anti-glare | Anti-glare | Reflected | |
|---|---|---|---|---|---|---|---|
| | | Tt | Hz | property | property | scattered | Scratch |
| | AM1/AM2 | (%) | (%) | 1 | 2 | light | resistance |
| Example 1 | 42.36 | 90.4 | 76.5 | A | A | A | B |
| Example 2 | 78.00 | 90.7 | 60.9 | A | A | B | A |
| Example 3 | 50.98 | 90.6 | 71.4 | A | A | A | A |
| Example 4 | 54.21 | 89.8 | 78.5 | A | A | B | A |
| Example 5 | 13.76 | 89.8 | 85.1 | A | A | B | B |
| Example 6 | 53.85 | 90.7 | 52.6 | A | A | B | A |
| Example 7 | 50.89 | 92.8 | 69.3 | A | A | A | A |
| Comparative | 34.74 | 89.2 | 74.5 | B | B | B | C |
| Example 1 | | | | | | | |
| Comparative | 145.14 | 90.7 | 22.5 | B | B | C | A |
| Example 2 | | | | | | | |
| Comparative | 7.03 | 69.1 | 98.0 | A | A | C | C |
| Example 3 | | | | | | | |
| Comparative | 28.17 | 85.4 | 88.4 | A | A | C | B |
| Example 4 | | | | | | | |

TABLE 2

| | Δq | λq | Rq | Transmitted image clearness (%) | | | | | |
|---|---|---|---|---|---|---|---|---|---|
| | [μm/μm] | [μm] | [μm] | 0.125 mm | 0.25 mm | 0.5 mm | 1.0 mm | 2.0 mm | Total |
| Example 1 | 0.508 | 12.326 | 0.705 | 2.9 | 2.5 | 2.7 | 4.1 | 8.6 | 18.3 |
| Example 2 | 0.391 | 15.925 | 0.701 | 10.5 | 10.1 | 8.8 | 10.4 | 20.4 | 50.1 |
| Example 3 | 0.628 | 13.371 | 0.945 | 3.2 | 2.0 | 2.6 | 3.3 | 7.6 | 16.7 |
| Example 4 | 0.703 | 13.284 | 1.051 | 2.8 | 1.6 | 2.3 | 2.8 | 7.7 | 15.6 |
| Example 5 | 0.714 | 10.603 | 0.852 | 14.5 | 16.3 | 18.8 | 18.5 | 21.2 | 73.0 |
| Example 6 | 0.320 | 16.022 | 0.577 | 11.7 | 11.0 | 11.8 | 11.7 | 18.1 | 53.3 |
| Example 7 | 0.588 | 13.041 | 0.863 | 3.5 | 2.6 | 3.1 | 3.5 | 8.1 | 18.2 |
| Comparative | 0.386 | 10.865 | 0.472 | 55.0 | 56.1 | 56.8 | 58.5 | 58.7 | 229.0 |
| Example 1 | | | | | | | | | |
| Comparative | 0.262 | 19.026 | 0.561 | 3.5 | 2.5 | 2.2 | 4.0 | 18.2 | 27.9 |
| Example 2 | | | | | | | | | |
| Comparative | 0.563 | 9.248 | 0.586 | 37.2 | 25.4 | 29.2 | 31.9 | 41.9 | 140.2 |
| Example 3 | | | | | | | | | |
| Comparative | 0.824 | 12.530 | 1.162 | 13.2 | 12.6 | 45.8 | 14.1 | 21.9 | 95.0 |
| Example 4 | | | | | | | | | |

(Note:
a total value of the transmitted image clearness is a value excluding C_{0.25}.)

From the results in Table 1, it can be confirmed that the anti-glare film of Examples has excellent anti-glare properties and scratch resistance, suppresses reflected scattered light, and has an excellent jet-black appearance.

It is presumed that a major cause of the small AM1 in Comparative Example 1 is the high content of the inorganic fine particles to suppress flow of the organic particles. It is presumed that a major cause of the small AM2 in Comparative Example 2 is the small amount of the irregularly shaped silica to widen the intervals of the convex portions. It is presumed that a major cause of the large AM2 in Comparative Example 3 is the large amount of spread organic particles to narrow the intervals of the convex portions. It is presumed that a major cause of the large AM1 in Comparative Example 4 is the large amount of the irregularly shaped silica, which tends to increase AM 1.

### REFERENCE SIGNS LIST

10: transparent substrate
20: anti-glare layer
21: binder resin
22: particles
100: anti-glare film
110: display element
120: image panel
200: observer

1. An anti-glare film comprising an anti-glare layer, the anti-glare film having an uneven surface, wherein
for an amplitude spectrum of elevation of the uneven surface, when a sum of amplitudes corresponding to spatial frequencies of 0.005 μm⁻¹, 0.010 μm⁻¹, and 0.015 μm⁻¹ is defined as AM1 and an amplitude at a spatial frequency of 0.300 μm⁻¹ is defined as AM2, AM1 is more than 0.4000 μm and 1.0000 μm or less, and AM2 is 0.0050 μm or more and 0.0500 μm or less.

2. The anti-glare film according to claim 1, wherein AM1/AM2 is 1.0 or more and 90.0 or less.

3. The anti-glare film according to claim 1, wherein when a root mean square inclination of the uneven surface is defined as Δq and a root mean square wavelength of the uneven surface is defined as λq, Δq is 0.250 μm/μm or more and λq is 17.000 μm or less.

4. The anti-glare film according to claim 1, wherein when a root mean roughness of the uneven surface is defined as Rq, Rq is 0.300 μm or more.

5. The anti-glare film according to claim 1, having a haze of 40% or more and 98% or less according to JIS K7136:2000.

6. The anti-glare film according to claim 1, wherein the anti-glare layer contains a binder resin and particles.

7. The anti-glare film according to claim 6, wherein when a thickness of the anti-glare layer is defined as T and an average particle size of the particles is defined as D, D/T is 0.20 or more and 0.96 or less.

8. The anti-glare film according to claim 6, wherein the particles are contained in an amount of 10 parts by mass or more and 200 parts by mass or less based on 100 parts by mass of the binder resin.

9. The anti-glare film according to claim 6, wherein the particles are inorganic particles.

10. The anti-glare film according to claim 9, wherein the anti-glare layer further comprises organic particles.

11. The anti-glare film according to claim 6, wherein the binder resin comprises a cured product of an ionizing radiation-curable resin composition and a thermoplastic resin.

12. The anti-glare film according to claim 1, further comprising an anti-reflection layer on the anti-glare layer, a surface of the anti-reflection layer being the uneven surface.

13. A polarizing plate comprising:
a polarizer;
a first transparent protective plate disposed on one side of the polarizer; and
a second transparent protective plate disposed on the other side of the polarizer, wherein
at least one of the first transparent protective plate and the second transparent protective plate is the anti-glare film according to claim 1, and
a surface opposite to the uneven surface of the anti-glare film and the polarizer are disposed so as to face each other.

14. A surface plate for an image display device, the surface plate comprising:
a resin plate or a glass plate; and
a protective film bonded to the resin plate or the glass plate, wherein
the protective film is the anti-glare film according to claim 1, and
a surface opposite to the uneven surface of the anti-glare film and the resin plate or the glass plate are disposed so as to face each other.

15. An image display panel comprising:
a display element; and
an optical film disposed on a light-emitting surface side of the display element, wherein
the image display panel comprises the anti-glare film according to claim 1 as the optical film, and
the anti-glare film is disposed so that a surface of the anti-glare film on the uneven surface side is disposed so as to face the opposite side to the display element.

16. An image display device comprising the image display panel according to claim 15, wherein the anti-glare film is disposed on an outermost surface.
